(19) United States
(12) Patent Application Publication
(10) Pub. No.: US 2017/0117147 A1
(43) Pub. Date: Apr. 27, 2017

(54) FACET-SELECTIVE GROWTH OF NANOSCALE WIRES

(71) Applicant: President and Fellows of Harvard College, Cambridge, MA (US)

(72) Inventors: Charles M. Lieber, Lexington, MA (US); Max Nathan Mankin, Cambridge, MA (US); Robert Day, Somerville, MA (US); Ruixuan Gao, Cambridge, MA (US)

(73) Assignee: President and Fellows of Harvard College, Cambridge, MA (US)

(21) Appl. No.: 15/317,997

(22) PCT Filed: Jun. 11, 2015
(86) PCT No.: PCT/US2015/035317

§ 371 Date: Dec. 12, 2016

Related U.S. Application Data
(60) Provisional application No. 62/011,796, filed on Jun. 13, 2014.

(51) Int. Cl. H01L 21/02; H01L 29/06; H01L 29/04; H01L 21/311

(52) U.S. Cl. CPC H01L 21/02433; H01L 21/31116; H01L 21/02238; H01L 21/02381; H01L 21/02557; H01L 21/02543; H01L 21/02532; H01L 21/02178; H01L 21/02164; H01L 21/0217; H01L 21/02658; H01L 29/0669; H01L 29/045; B82Y 40/00

(57) ABSTRACT

The present invention generally relates to nanoscale wires, and to systems and methods of producing nanoscale wires. In some aspects, the present invention is generally related to facet-specific deposition on semiconductor surfaces. In one embodiment, a first surface of a nanoscale wire, or a semiconductor, is preferentially oxidized relative to a second surface, and material is preferentially deposited on the second surface relative to the first surface. For example, the nanoscale wire or semiconductor may be a silicon nanowire that is initially exposed to an etchant to remove silicon oxide, then exposed to an oxidant under conditions such that one facet or surface (e.g., a {113} facet) is oxidized more quickly than another facet or surface (e.g., a {111} facet). Material may then be deposited or immobilized on the less-oxidized facet relative to the more-oxidized facet. Other embodiments of the invention may be directed to articles made thereby, devices containing such nanoscale wires or semiconductors, kits involving such nanoscale wires or semiconductors, semiconductor surfaces, or the like.

### RELATED APPLICATIONS

This application claims the benefit of U.S. Provisional Patent Application Ser. No. 62/011,796, filed Jun. 13, 2014, entitled “Facet-Selective Growth of Nanoscale Wires,” by Lieber, et al., incorporated herein by reference in its entirety.

### GOVERNMENT FUNDING

This invention was made with government support under Grant No. N00244-09-1-0078 awarded by the Department of Defense. The government has certain rights in the invention.

### FIELD

The present invention generally relates to nanoscale wires, and to systems and methods of producing nanoscale wires. In some aspects, the present invention is generally related to facet-specific deposition on semiconductor surfaces.

### BACKGROUND

Interest in nanotechnology, in particular sub-microelectronic technologies such as semiconductor quantum dots and nanowires, has been motivated by the challenges of chemistry and physics at the nanoscale, and by the prospect of utilizing these structures in electronic and related devices. Nanoscopic articles might be well-suited for transport of charge carriers and excitons (e.g. electrons, electron pairs, etc.) and thus may be useful as building blocks in nanoscale applications.

### SUMMARY

The present invention generally relates to nanoscale wires, and to systems and methods of producing nanoscale wires. In some aspects, the present invention is generally related to facet-specific deposition on semiconductor surfaces. The subject matter of the present invention involves, in some cases, interrelated products, alternative solutions to a particular problem, and/or a plurality of different uses of one or more systems and/or articles.

In one aspect, the invention is directed to a method. In one set of embodiments, the method includes acts of removing silicon oxide from at least a portion of a nanoscale wire comprising a silicon surface, oxidizing a first facet of the nanoscale wire relative to a second facet, and preferentially depositing material on the second facet relative to the first facet.

The method, in another set of embodiments, includes acts of applying an etchant to a nanoscale wire comprising a silicon surface, oxidizing a first facet of the etched nanoscale wire relative to a second facet, and preferentially depositing material on the second facet relative to the first facet.

In yet another set of embodiments, the method includes acts of removing silicon oxide from at least a portion of a faceted nanoscale wire, freeze-drying the nanoscale wire, and preferentially depositing material on a second facet relative to a first facet of the nanoscale wire.

The method, in still another set of embodiments, includes acts of preferentially oxidizing a first facet of a faceted nano scale wire relative to a second facet, and preferentially depositing material on the second facet of the nanoscale wire relative to the first facet.

According to yet another set of embodiments, the method includes acts of removing an oxide from at least a portion of a surface of a crystalline semiconductor nanoscale wire, oxidizing a first facet of the nano scale wire relative to a second facet, and preferentially depositing material on the second facet relative to the first facet.

In one set of embodiments, the method includes acts of applying an etchant to a crystalline nano scale wire, oxidizing a first facet of the etched nano scale wire relative to a second facet, and preferentially depositing material on the second facet relative to the first facet.

The method, in another set of embodiments, comprises acts of removing an oxide from at least a portion of a crystalline nanoscale wire, freeze-drying the nanoscale wire, and depositing material on a second facet relative to a first facet of the nanoscale wire.

According to yet another set of embodiments, the method includes acts of removing an oxide from at least a portion of a surface of a semiconductor, oxidizing a first facet of the surface relative to a second facet, and preferentially depositing material on the second facet relative to the first facet.

In still another set of embodiments, the method includes acts of applying an etchant to a crystalline surface, oxidizing a first facet of the etched surface relative to a second facet, and preferentially depositing material on the second facet relative to the first facet.

The method, in another set of embodiments, includes acts of removing an oxide from at least a portion of a crystalline surface, freeze-drying the surface, and depositing material on a second facet relative to a first facet of the surface.

In still another set of embodiments, the method comprises acts of preferentially oxidizing a first facet of a crystalline surface relative to a second facet, and preferentially depositing material on the second facet relative to the first facet.

According to one set of embodiments, the method includes acts of removing silicon oxide from at least a portion of a faceted nanoscale wire, critical point drying the nanoscale wire, and preferentially depositing material on a second facet relative to a first facet of the nano scale wire.

According to another set of embodiments, the method includes acts of removing an oxide from at least a portion of a crystalline nanoscale wire, critical point drying the nanoscale wire, and depositing material on a second facet relative to a first facet of the nano scale wire.

In yet another set of embodiments, the method includes acts of removing an oxide from at least a portion of a crystalline surface, critical point drying the surface, and depositing material on a second facet relative to a first facet of the surface.

The method, in accordance with still another set of embodiments, includes removing silicon oxide from at least a portion of a nanoscale wire comprising a silicon surface, oxidizing a first facet of the nano scale wire relative to a second facet, and preferentially depositing material on the first facet relative to the second facet.

In another set of embodiments, the method includes acts of applying an etchant to a nanoscale wire comprising a silicon surface, oxidizing a first facet of the etched nanoscale wire relative to a second facet, and preferentially depositing material on the first facet relative to the second facet.

The method, in yet another set of embodiments, includes acts of removing silicon oxide from at least a portion of a faceted nanoscale wire, freeze-drying the nanoscale wire, and preferentially depositing material on a first facet relative to a second facet of the nano scale wire.

In still another set of embodiments, the method includes acts of preferentially oxidizing a first facet of a faceted nano scale wire relative to a second facet, and preferentially depositing material on the first facet of the nanoscale wire relative to the second facet.

In yet another set of embodiments, the method includes acts of removing an oxide from at least a portion of a surface of a crystalline semiconductor nanoscale wire, oxidizing a first facet of the nanoscale wire relative to a second facet, and preferentially depositing material on the first facet relative to the second facet.

According to one set of embodiments, the method comprises acts of applying an etchant to a crystalline nanoscale wire, oxidizing a first facet of the etched nanoscale wire relative to a second facet, and preferentially depositing material on the first facet relative to the second facet.

In accordance with another set of embodiments, the method comprises acts of removing an oxide from at least a portion of a crystalline nanoscale wire, freeze-drying the nanoscale wire, and depositing material on a first facet relative to a second facet of the nanoscale wire.

In yet another set of embodiments, the method includes acts of removing an oxide from at least a portion of a surface of a semiconductor, oxidizing a first facet of the surface relative to a second facet, and preferentially depositing material on the first facet relative to the second facet.

The method includes, in still another set of embodiments, acts of applying an etchant to a crystalline surface, oxidizing a first facet of the etched surface relative to a second facet, and preferentially depositing material on the first facet relative to the second facet.

In one set of embodiments, the method comprises acts of removing an oxide from at least a portion of a crystalline surface, freeze-drying the surface, and depositing material on a first facet relative to a second facet of the surface.

In another set of embodiments, the method includes acts of preferentially oxidizing a first facet of a crystalline surface relative to a second facet, and preferentially depositing material on the first facet relative to the second facet.

Yet another set of embodiments is generally directed to a method comprising acts of removing silicon oxide from at least a portion of a faceted nanoscale wire, critical point drying the nanoscale wire, and preferentially depositing material on a second facet relative to a first facet of the nanoscale wire.

The method, in yet another set of embodiments, comprises removing an oxide from at least a portion of a crystalline nanoscale wire, critical point drying the nanoscale wire, and depositing material on a second facet relative to a first facet of the nanoscale wire.

In still another set of embodiments, the method includes acts of removing an oxide from at least a portion of a crystalline surface, critical point drying the surface, and depositing material on a second facet relative to a first facet of the surface.

The method, in one set of embodiments, includes acts of removing an oxide from at least a portion of a crystalline semiconductor surface using an etchant, freeze-drying the surface, preferentially oxidizing a first facet of the crystalline semiconductor surface relative to a second facet, and preferentially depositing material on the second facet relative to the first facet.

In another aspect, the present invention is generally directed to a composition. In one set of embodiments, the composition comprises a silicon nanoscale wire comprising a first facet and a second facet, and a material positioned on the first facet but not the second facet. In some cases, the interface between the first facet and the silicon nanoscale wire is substantially free of oxygen.

In yet another aspect, the present invention encompasses methods of making one or more of the embodiments described herein, for example, nanoscale wires. In still another aspect, the present invention encompasses methods of using one or more of the embodiments described herein, for example, nanoscale wires.

Other advantages and novel features of the present invention will become apparent from the following detailed description of various non-limiting embodiments of the invention when considered in conjunction with the accompanying figures. In cases where the present specification and a document incorporated by reference include conflicting and/or inconsistent disclosure, the present specification shall control. If two or more documents incorporated by reference include conflicting and/or inconsistent disclosure with respect to each other, then the document having the later effective date shall control.

### BRIEF DESCRIPTION OF THE DRAWINGS

Non-limiting embodiments of the present invention will be described by way of example with reference to the accompanying figures, which are schematic and are not intended to be drawn to scale. In the figures, each identical or nearly identical component illustrated is typically represented by a single numeral. For purposes of clarity, not every component is labeled in every figure, nor is every component of each embodiment of the invention shown where illustration is not necessary to allow those of ordinary skill in the art to understand the invention. In the figures:

FIGS. 1A-1B illustrate deposition on faceted nanowires, in one embodiment of the invention;

FIGS. 2A-2E illustrate TEM imaging of faceted nanowires, in another embodiment of the invention;

FIGS. 3A-3E illustrate TEM imaging of a heterostructure nanowire, in yet another embodiment of the invention;

FIG. 4 illustrates a faceted nanowire, in still another embodiment of the invention;

FIGS. 5A-5B illustrates heterostructure nanowires, in other embodiments of the invention;

FIGS. 6A-6B illustrate TEM characterization of nanowires, in yet another embodiment of the invention;

FIGS. 7A-7D illustrate certain nanowires, in still another embodiment of the invention;

FIGS. 8A-8D illustrate certain growth experiments, in another embodiment of the invention;

FIGS. 9A-9B illustrate characterization of certain heterostructure nanowires, in yet another embodiment of the invention;

FIGS. 10A-10C illustrate deposition on doped nanowires, in still another embodiment of the invention; and

FIGS. 11A-11C illustrate various silicon nanowires, in another embodiment of the invention.

### DETAILED DESCRIPTION

The present invention generally relates to nanoscale wires, and to systems and methods of producing nanoscale wires. In some aspects, the present invention is generally related to facet-specific deposition on semiconductor surfaces. In one embodiment, a first surface of a nanoscale wire, or a semiconductor, is preferentially oxidized relative to a second surface, and material is preferentially deposited on the second surface relative to the first surface. For example, the nanoscale wire or semiconductor may be a silicon nanowire that is initially exposed to an etchant to remove silicon oxide, then exposed to an oxidant under conditions such that one facet or surface (e.g., a {113} facet) is oxidized more quickly than another facet or surface (e.g., a {113} facet). Material may then be deposited or immobilized on the less-oxidized facet relative to the more-oxidized facet. Other embodiments of the invention may be directed to articles made thereby, devices containing such nanoscale wires or semiconductors, kits involving such nanoscale wires or semiconductors, semiconductor surfaces, or the like.

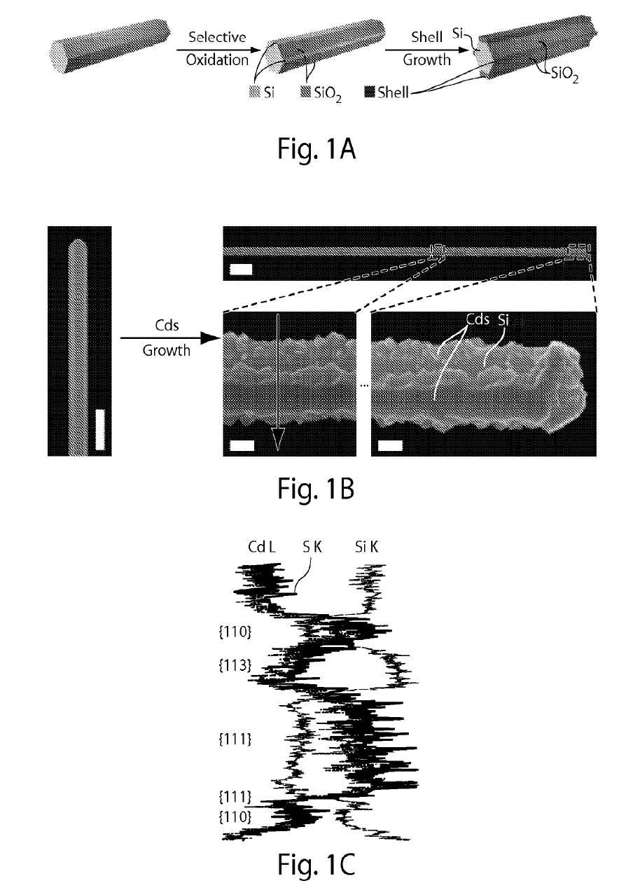

For instance, in one aspect, the present invention is generally directed to systems and methods for preferentially depositing material onto a nanoscale wire on one surface, relative to another surface. For example, FIG. 1A shows a faceted or crystalline nanowire having a number of exposed crystalline surfaces or facets. Typically, these facets are referred to using Miller indexes, e.g., {110}, {111}, {113}, etc. In some embodiments, one of the facets can be preferentially oxidized relative to another facet, where the oxidation of a facet may slow or prevent deposition of material onto that facet. Thus, facets that are relatively less oxidized (or not oxidized) may exhibit greater deposition of material.

FIG. 1A illustrates that selective oxidation may be performed on one facet relative to another facet of the nanowire. For example, the nanowire may be a silicon nanowire, and certain facets (e.g., the {113} facet) may be selectively oxidized, relative to other facets (e.g., the {111} or {110} facets). In other embodiments, however, other materials, such as germanium, may also be used, e.g., as discussed below. Selective oxidation of the nanowire may be performed in a number of ways. As an example, the silicon nanowire may be grown in an oxygen-free environment, and/or any silicon oxide present on the nanowire may initially be removed, e.g., by exposure to a suitable etchant. Afterwards, the silicon nanowire may be exposed to a suitable oxygen source (e.g., water). Without wishing to be bound by any theory, it is believed that certain molecules can bind to or “stick” to the nanowire, preferentially binding to some surfaces relative to other surfaces. Water or other suitable oxygen-containing compounds can preferentially bind to the {113} facet and may react with silicon to produce silicon oxide, preferentially on the {113} facet relative to other facets of the nanowire.

After formation of silicon oxide, a material is patterned or deposited onto the silicon nanowire as is shown in the example of FIG. 1A. The shell material may be any suitable material, e.g., germanium, InP, or CdS. Other examples are discussed below. Due to the presence of silicon oxide on certain facets of the nanowire, the shell material is preferentially deposited on certain facets (e.g., the {111} or {110} facets), relative to other facets (e.g., the {113} facet). The unoxidized silicon facets may facilitate deposition of other materials, relative to other facets with silicon oxide on their surfaces. In such a manner, anisotropic deposition of the shell material on the nanowire may occur.

While the above example uses crystalline or faceted silicon nanowires, it should be understood that this is by way of example only, and that other types of nanoscale wires may be used in other embodiments of the invention. In addition, similar techniques can be used to preferentially deposit material on one surface of a semiconductor, such as a crystalline semiconductor, relative to another surface of the semiconductor. In some embodiments, the nanoscale wire or semiconductor, or at least a portion thereof, may be crystalline or have a regularly ordered arrangement of atoms. If a nanoscale wire is used, the nanoscale wire may be straight or bent, and in some cases, may contain more than one region, e.g., a core and a shell surrounding at least the portion of the core. Examples of suitable nanowires include those discussed in U.S. Ser. No. 13/497,852, filed Mar. 21, 2012, entitled “Bent Nanowires and Related Probing of Species,” published as U.S. Pat. Apl. Pub. No. 2012/0267604 on Oct. 25, 2012; or U.S. Patent Application Ser. No. 61/989,904, filed May 7, 2014, entitled “Controlled Growth of Nanoscale Wires,” by Lieber, et al., each incorporated herein by reference in its entirety.

In one set of embodiments, material may be deposited onto a semiconductor surface, e.g., which may be crystalline. For example, the semiconductor may be silicon, germanium, or other semiconductors such as those described herein. As non-limiting examples, the semiconductor surface may be planar (e.g., as in the surface of a wafer), the semiconductor nanoscale wire, etc. In some cases, the semiconductor surface may comprise more than one exposed facet. For example, a silicon semiconductor surface may have certain exposed facets, such as one or more of the {111}, {110}, {100}, or {113} facets.

In some embodiments, material may be deposited onto a nanoscale wire. For example, the nanoscale wire may be formed from a single crystal, for example, a single crystal nanoscale wire comprising a semiconductor. While such a single crystal item may include defects in the crystal in some cases, the single crystal item is distinguished from an item that includes one or more crystals, not ionically or covalently bonded, but merely in close proximity to one another. In other embodiments, however, the nanoscale wire may comprise more than one crystal. In addition, as discussed below, the nanoscale wire may be formed of other semiconductor materials, such as germanium, that can be oxidized.

In certain embodiments, the nanoscale wire or semiconductor may include at least one exposed portion that is crystalline. Typically, a crystalline material comprises a number of surfaces or facets that define the outer boundaries of the crystalline material, e.g., that are exposed to air or another material (e.g., another material deposited thereon). As a non-limiting example, silicon is typically exposed on the {111}, {011}, {100}, and {113} facets.

Accordingly, in certain embodiments of the invention, material may be preferentially deposited on a faceted nanoscale wire or a semiconductor surface, where the material is deposited preferentially on a second facet relative to a first facet of the nanoscale wire or semiconductor (or vice versa). For instance, in a silicon surface comprising {111}, {011}, and {113} facets, a deposited material (for example, another semiconductor material such as silicon, germanium, InP, CdS, etc.) may be preferentially deposited on the {011} facet relative to the {113} facet, on the {113} facet relative to the {011} facet, on the {111} facet relative to the {113} facet, on the {113} facet relative to the {111} facet, etc. In some cases, material may be deposited onto the second facet while substantially no (or at least undetectable amounts of) material is deposited onto the first facet. In other embodiments, some material may be deposited onto the first facet, but is substantially less than the second facet. For instance, the first facet may have a thickness of deposited material that is less than about 50%, less than about 40%, less than about 30%, less than about 20%, or less than about 10% of the thickness of the deposited material on the second facet.

The deposited material may be any material that can be deposited on the nanoscale wire or semiconductor surface. For example, in one set of embodiments, the deposited material may be a semiconductor material, such as silicon or germanium. Other non-limiting examples include InP and CdS. Still other examples include, but are not limited to, GaAs, silicon nitride, or silicon oxide nitride or mixed SiₓO_{y}N_{z} compounds, CdTe, CdSe, InAs, GaN, AN, GaAlAs, GaAlN, ZnS, ZnSe, SiC, InSe, BN, BP, BAs, AlP, AlAs, AlSb, GaP, GaAs, GaSb, InN, InSb, ZnO, ZnTe, CuCl, Cu₂S, PbSe, PbS, PbTe, SnS, SnS₂, PbSnTe, MoS₂, PbI₂, GaSe, InGaAs, InGaAlAs, etc. In some cases, the deposited material is one that preferentially deposits on native or unmodified facets of a semiconductor material, relative to oxidized facets of the semiconductor material. In some cases, the deposited material, prior to deposition, is exposed to the nanoscale wire or semiconductor surface as a gas, e.g., GeH₄ in the case of germanium or SiH₄ in the case of silicon. The deposited material may have the same composition, or a different composition, than the surface. In some cases, the two materials may also have the same crystal structure. In certain embodiments, the material that is deposited onto the surface may be epitaxial to the nanoscale wire at the deposition region, e.g., exhibiting identical symmetries or minimal lattice mismatches, or the like. The deposited material may also be crystalline after deposition, in some cases.

In certain embodiments, however, the deposited material is one that preferentially deposits oxidized facets of the semiconductor material, relative to native or unmodified facets of a semiconductor material. Examples include, but are not limited to, “getter” or ion-scavenging materials. For example, certain metals such as Ga, Ba, etc. will preferentially deposit on oxides relative to other surfaces. Other materials that may preferentially deposit onto oxidized facets or surfaces include, but are not limited to, As, Ti, Cr, Zr, Fe, Co, V, Al, Li, Na, K, Rb, Cs, Mg, Ca, Sc, Nb, Mn, Ni, Zn, and Ce as well as certain dielectrics such as aluminum oxide, silicon oxide, silicon nitride, etc.

In addition, in some cases, the interface between the surface and the deposited material may be substantially free of oxygen. For example, there may be no detectable oxygen present at the interface, and/or there may be a trace amount of oxygen present, but not sufficient to disrupt the interface between the surface and the deposited material.

Other non-limiting examples of suitable deposition materials include those described in International Patent Application No. PCT/US2014/014596, filed Feb. 4, 2014, entitled “Anisotropic Deposition in Nanoscale Wires,” by Lieber, et al.; or U.S. Patent Application Ser. No. 61/989,904, filed May 7, 2014, entitled “Controlled Growth of Nanoscale Wires,” by Lieber, et al., each incorporated herein by reference in their entireties

As mentioned, preferential deposition of material on the nanoscale wire or semiconductor surface may be controlled by controlling the formation of an oxide on a surface or facet of the nanoscale wire or semiconductor surface, which may be used to slow or prevent deposition (or enhance deposition) onto those facets, relative to other facets. Accordingly, facets which are not substantively altered, e.g., by oxidation, may exhibit increased or decreased deposition of material, relative to other facets which are substantively altered. For example, a surface may be oxidized by exposing the nanoscale wire to a suitable source of oxygen, e.g., oxygen-containing compounds. Examples include, but are not limited to, air or water. Oxygen gas may also be used in some cases. Other non-limiting examples of suitable oxidants include ozone, chlorites, chlorates, perchlorites, acids, ferrocenium or other metal-containing ions, permanganate, chromate, osmium tetroxide, meta-chloroperoxybenzoic acid, perchlorate, hydrogen peroxide, peroxides in general, fluorine, chlorine, bromine, iodine, nitric acid, nitrates, sulfuric acid, peroxydisulfuric acid, peroxymonosulfuric acid, hypochlorite, nitrous oxide, silver oxide, potassium nitrate, tollens' reagent, alcohols, carboxylic acids, esters, and/or ketones, 2,2′-dipyridyldisulfide, chromic or dichromic acid, chromium trioxide, pyridium chlorochromate (PCC), and other chromate/dichromate compounds. In some embodiments, the oxidant is a gas, e.g., ozone, fluorine, chlorine, bromine, iodine, or vaporized organics containing oxygen-containing functional groups. In addition, in one set of embodiments, electrochemical methods of oxidation may be used to control the formation of an oxide on a surface or facet of the nanoscale wire or semiconductor surface.

Thus, for example, a nanowire or semiconductor surface may be exposed to a oxygen-containing compound from a source of oxygen, which may interact with the surface such that the oxygen-containing compound binds to certain facets relative to other facets, and forms an oxide on those facets, e.g., by binding to atoms within the nanoscale wire. Non-limiting examples include the formation of silicon oxide on silicon surfaces and germanium oxide (GeO₂) on germanium surfaces. Other examples include, but are not limited to, GaAs oxide on GaAs surfaces, InP oxide on InP surfaces, InAs oxide on InAs surfaces, AlAs oxide on AlAs surfaces, GaP oxide on GaP surfaces, AlGaP oxide on AlGaP surfaces, InGaP oxide on InGaP surfaces, InGaAs oxide on InGaAs surfaces, InGaAsP oxide on InGaAsP surfaces, AlGaAs oxide on AlGaAs surfaces, InAlGaAs oxide on InAlGaAs surfaces, InAlGaAsP oxide on InAlGaAsP surfaces, CdTe oxide on CdTe surfaces, CdSe oxide on CdSe surfaces, CdS oxide on CdS surfaces, etc.

In addition, in some cases, nitrides may be used in place of oxides as discussed herein. For instance, a nanoscale wire or other substrate surface may be exposed to an N-containing molecule such that nitrides form on selected surfaces or facets, relative to other surfaces or facets. Thus, for example, a silicon nanowire may be exposed to N-containing molecules such as amines, ammonia, ammonium salts, etc., to preferentially produce silicon nitrides on certain facets of the nanowire, relative to other facets. The silicon nitrides may be used to inhibit (or enhance) deposition of materials such as those discussed herein onto those surfaces or facets, relative to other facets.

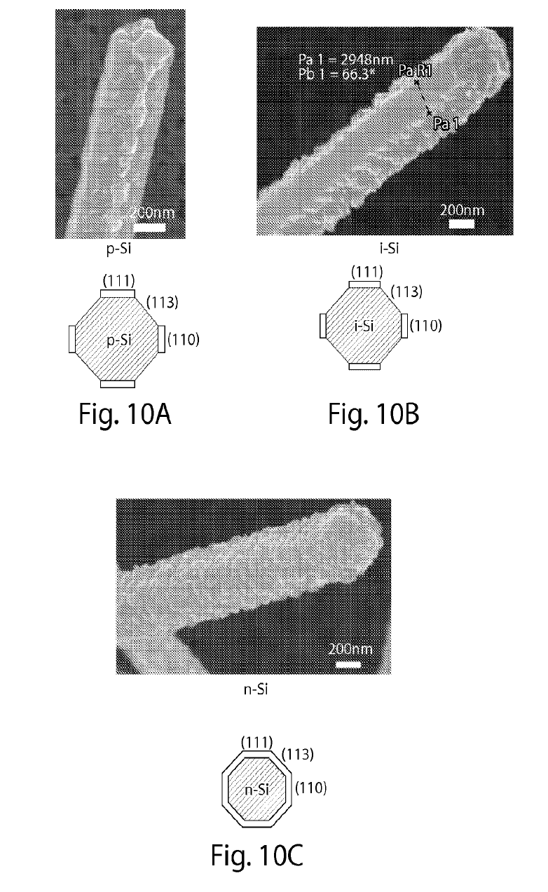

In addition, the amount of deposition that forms on the surface wire may also be controlled in some cases by the amount of dopants or impurities in the nanoscale wire semiconductor surface, e.g., exposed to the surface or facet where deposition occurs. For example, n-type dopants in a nanoscale wire or semiconductor surface may disrupt selectivity of deposition, resulting in more uniform doping, compared to other surfaces or facets that are undoped or contain p-type dopants. For instance, as is shown in FIG. 10, a silicon nanowire that is p-doped or undoped (i-Si) may exhibit selective or anisotropic deposition. In another embodiment, facet-selectivity may be disrupted by “burying” the mask layer, e.g., using an oxide, nitride, some other dielectric, etc., or other deposition materials such as those discussed herein. For example, in one set of embodiments, every surface of the nanoscale wire or semiconductor surface may be covered, e.g., whether or not an oxide present on the surface. This may be accomplished, for example, by depositing films at an extremely rapid rate, or by depositing an adhesive layer that adheres to both the oxidized and non-oxidized surfaces.

It should also be understood that many materials, such as silicon, germanium, InP, silicon nitride, GaAs, etc., can form an oxide layer upon exposure to a source of oxygen, such as air or water. The exposed facets of the nanoscale wire or semiconductor surface may thus form a layer of oxide (e.g., silicon oxide, germanium oxide, indium phosphide oxide, silicon nitride oxide, GaAs oxide, etc.), during formation of the surface, e.g., if at least trace amounts of air or water are present. Accordingly, in certain embodiments, the nanoscale wire or semiconductor surface must be processed to avoid the formation of certain or all oxides, and/or to remove certain or all oxides that might be present. This may be advantageous in some embodiments since materials such as silicon or germanium naturally form oxides, e.g., upon exposure to air, and thus, no external agents are required to be applied to the surface (and which could themselves adversely react with the surface) in order to cause selective deposition of materials onto certain facets, relative to other facets.

For instance, in one set of embodiments, a nanoscale wire or semiconductor surface may be grown under conditions in which sources of oxygen, such as air or water, are not present. In addition, in some embodiments, the nanoscale wire or semiconductor surface may be grown in a reducing atmosphere (e.g., comprising H₂) such that any oxygen that may be present is not able to form an oxide, or at least its ability to form an oxide is reduced.

In another set of embodiments, oxides that are present on the surface may be removed, for example through etching. Etchants that may be used include, but are not limited to HF or buffered HF, a peroxide such as H₂O₂, KOH, I₂/KI, ethylene diamine and pyrocatechol, iron chloride, plasmas such as CCl₄ or CF₄ plasma, tetramethylammonium hydroxide, or the like. In some cases, the nanoscale wire or semiconductor surface is exposed to the etchant such that one or more surface layers, or at least a portion thereof, is removed.

In some embodiments, water (e.g., as an oxygen source), solvents, or other oxidants solutions may be removed through a freeze-drying process. Those of ordinary skill in the art will be aware of freeze-drying techniques suitable for nanoscale wire production. For example, a nanoscale wire or semiconductor surface may be exposed to a temperature below 0° C., such as −20° C. or less, −50° C. or less, −75° C. or less, −100° C. or less, −150° C. or less, or −196° C. or less. For instance, the nanoscale wire or semiconductor surface may be exposed to liquid nitrogen or dry ice. The nanoscale wire or semiconductor surface may also be exposed to a pressure less than atmospheric or ambient pressure, e.g., less than about 700 Torr, less than about 500 Torr, less than about 300 Torr, less than about 100 Torr, less than about 50 Torr, less than about 30 Torr, less than about 10 Torr, less than about 5 Torr, less than about 3 Torr, less than about 1 Torr, less than about 500 mTorr, less than about 300 mTorr, less than about 100 mTorr, less than about 50 mTorr, less than about 30 mTorr, less than about 10 mTorr, etc.

In certain embodiments, water, solvents, or other oxidants solutions, may be removed through critical point drying. In critical point drying processes, the water is removed by drying under supercritical conditions (i.e., supercritical relative to water, which has a critical point at around 647 K and 22.064 MPa). Those of ordinary skill in the art will be aware of drying techniques suitable for nanoscale wire production. For instance, the temperature may be at least about 650 K, at least about 675 K, at least about 700 K, at least about 750 K, at least about 800 K, at least about 900 K, at least about 1000 K. The pressure may be, for example, at least about 23 MPa, at least about 24 MPa, at least about 25 MPa, at least about 30 MPa, at least about 35 MPa, at least about 40 MPa, etc.

Other techniques for modifying or altering the nanoscale wire or semiconductor surface may also be applied, e.g., during or after formation of the nanoscale wire. For example, in certain aspects, additional materials may be deposited onto the surface and/or the deposited material. The additional materials may be deposited using any suitable technique, and may be deposited isotropically or anisotropically. In some embodiments, for example, additional materials may be deposited using the techniques discussed herein.

As another example, in some cases, a portion of a nanoscale wire or semiconductor surface formed as discussed herein may be etched or otherwise removed, e.g., after formation. In some embodiments, for instance, the deposited material may be removed, or a portion of the nanoscale wire or semiconductor surface (e.g., prior to or after addition of the deposited material) may be removed. Those of ordinary skill in the art will be aware of suitable etchants and other techniques for removing material from nanoscale wires or semiconductor surfaces. Examples of etchants that may be used include, but are not limited to e.g., a peroxide such as H₂O₂, KOH, I₂/KI, ethylene diamine and pyrocatechol, iron chloride, plasmas such as CCl₄ or CF₄ plasma, tetramethylammonium hydroxide, or the like.

As mentioned, any nanoscale wire can be used in any of the embodiments discussed herein, e.g., such that material may be deposited anisotropically or only or preferentially on certain surface facets. Non-limiting examples of suitable nanoscale wires include carbon nanotubes, nanorods, nanowires, organic and inorganic conductive and semiconducting polymers, metal nanoscale wires, semiconductor nanoscale wires (for example, formed from silicon or germanium), and the like. Other conductive or semiconducting elements that may not be nanoscale wires, but are of various small nanoscopic-scale dimension, also can be used in certain aspects.

In general, a “nanoscale wire” (also known herein as a “nanoscopic-scale wire” or “nanoscopic wire”) generally is a wire or other nanoscale object, that at any point along its length, has at least one cross-sectional dimension and, in some embodiments, two orthogonal cross-sectional dimensions (e.g., a diameter) of less than 1 micrometer, less than about 500 nm, less than about 200 nm, less than about 150 nm, less than about 100 nm, less than about 70, less than about 50 nm, less than about 20 nm, less than about 10 nm, less than about 5 nm, than about 2 nm, or less than about 1 nm. In some embodiments, the nanoscale wire is generally cylindrical. The nanoscale wire may also be faceted, i.e., the nanoscale wire may have a polygonal cross-section. The cross-section of a nanoscale wire can be of any arbitrary shape, including, but not limited to, circular, square, rectangular, annular, polygonal, or elliptical, and may be a regular or an irregular shape. The nanoscale wire can also be solid or hollow.

In some cases, the nanoscale wire has one dimension that is substantially longer than the other dimensions of the nanoscale wire. For example, the nanoscale wire may have a longest dimension that is at least about 1 micrometer, at least about 3 micrometers, at least about 5 micrometers, or at least about 10 micrometers or about 20 micrometers in length, and/or the nanoscale wire may have an aspect ratio (longest dimension to shortest orthogonal dimension) of greater than about 2:1, greater than about 3:1, greater than about 4:1, greater than about 5:1, greater than about 10:1, greater than about 25:1, greater than about 50:1, greater than about 75:1, greater than about 100:1, greater than about 150:1, greater than about 250:1, greater than about 500:1, greater than about 750:1, or greater than about 1000:1 or more in some cases.

In some embodiments, a nanoscale wire may be substantially uniform, or have a variation in average diameter of the nanoscale wire of less than about 30%, less than about 25%, less than about 20%, less than about 15%, less than about 10%, or less than about 5%. For example, the nanoscale wires may be grown from substantially uniform nanoclusters or particles, e.g., colloid particles. See, e.g., U.S. Pat. No. 7,301,199, issued Nov. 27, 2007, entitled “Nanoscale Wires and Related Devices,” by Lieber, et al., incorporated herein by reference in its entirety. In some cases, the nanoscale wire may be one of a population of nanoscale wires having an average variation in diameter, of the population of nanowires, of less than about 30%, less than about 25%, less than about 20%, less than about 15%, less than about 10%, or less than about 5%.

In some embodiments, a nanoscale wire has a conductivity of or of similar magnitude to any semiconductor or any metal. The nanoscale wire can be formed of suitable materials, e.g., semiconductors, metals, etc., as well as any suitable combinations thereof. In some cases, the nanoscale wire will have the ability to pass electrical charge, for example, being electrically conductive. For example, the nanoscale wire may have a relatively low resistivity, e.g., less than about 10⁻³ Ohmm, less than about 10⁻⁴ Ohm m, less than about 10⁻⁶ Ohm m, or less than about 10⁻⁷ Ohm m. The nanoscale wire can, in some embodiments, have a conductance of at least about 1 microsiemens, at least about 3 microsiemens, at least about 10 microsiemens, at least about 30 microsiemens, or at least about 100 microsiemens.

The nanoscale wire can be solid or hollow, in various embodiments. As used herein, a “nanotube” is a nanoscale wire that is hollow, or that has a hollowed-out core, including those nanotubes known to those of ordinary skill in the art. As another example, a nanotube may be created by creating a core/shell nanowire, then etching away at least a portion of the core to leave behind a hollow shell. Accordingly, in one set of embodiments, the nanoscale wire is a non-carbon nanotube. In contrast, a “nanowire” is a nanoscale wire that is typically solid (i.e., not hollow). Thus, in one set of embodiments, the nanoscale wire may be a semiconductor nanowire, such as a silicon nanowire.

In one set of embodiments, a nanoscale wire may comprise or consist essentially of a semiconductor. Typically, a semiconductor is an element having semiconductive or semi-metallic properties (i.e., between metallic and non-metallic properties). An example of a semiconductor is silicon. Other non-limiting examples include elemental semiconductors, such as gallium, germanium, diamond (carbon), tin, selenium, tellurium, boron, or phosphorous. In other embodiments, more than one element may be present in the nanoscale wire as the semiconductor, for example, gallium arsenide, gallium nitride, indium phosphide, cadmium selenide, etc. Still other examples include a Group II-VI material (which includes at least one member from Group II of the Periodic Table and at least one member from Group VI, for example, ZnS, ZnSe, ZnSSe, ZnCdS, CdS, or CdSe), or a Group III-V material (which includes at least one member from Group III and at least one member from Group V, for example GaAs, GaP, GaAsP, InAs, InP, AlGaAs, or InAsP).

In certain embodiments, the semiconductor can be undoped or doped (e.g., p-type or n-type). For example, in one set of embodiments, a nanoscale wire may be a p-type semiconductor nanoscale wire or an n-type semiconductor nanoscale wire, and can be used as a component of a transistor such as a field effect transistor (“FET”). For instance, the nanoscale wire may act as the “gate” of a source-gate-drain arrangement of a FET, while metal leads or other conductive pathways (as discussed herein) are used as the source and drain electrodes.

In some embodiments, a dopant or a semiconductor may include mixtures of Group IV elements, for example, a mixture of silicon and carbon, or a mixture of silicon and germanium. In other embodiments, the dopant or the semiconductor may include a mixture of a Group III and a Group V element, for example, BN, BP, BAs, AN, AlP, AlAs, AlSb, GaN, GaP, GaAs, GaSb, InN, InP, InAs, or InSb. Mixtures of these may also be used, for example, a mixture of BN/BP/BAs, or BN/AlP. In other embodiments, the dopants may include alloys of Group III and Group V elements. For example, the alloys may include a mixture of AlGaN, GaPAs, InPAs, GaInN, AlGaInN, GaInAsP, or the like. In other embodiments, the dopants may also include a mixture of Group II and Group VI semiconductors. For example, the semiconductor may include ZnO, ZnS, ZnSe, ZnTe, CdS, CdSe, CdTe, HgS, HgSe, HgTe, BeS, BeSe, BeTe, MgS, MgSe, or the like. Alloys or mixtures of these dopants are also be possible, for example, (ZnCd)Se, or Zn(SSe), or the like. Additionally, alloys of different groups of semiconductors may also be possible, for example, a combination of a Group II-Group VI and a Group III-Group V semiconductor, for example, (GaAs)ₓ(ZnS)₁₋ₓ. Other examples of dopants may include combinations of Group IV and Group VI elemnts, such as GeS, GeSe, GeTe, SnS, SnSe, SnTe, PbO, PbS, PbSe, or PbTe. Other semiconductor mixtures may include a combination of a Group I and a Group VII, such as CuF, CuCl, CuBr, CuI, AgF, AgCl, AgBr, AgI, or the like. Other dopant compounds may include different mixtures of these elements, such as BeSiN₂, CaCN₂, ZnGeP₂, CdSnAs₂, ZnSnSb₂, CuGeP₃, CuSi₂P₃, Si₃N₄, Ge₃N₄, Al₂O₃, (Al, Ga, In)₂(S, Se, Te)₃, Al₂CO, (Cu, Ag)(Al, Ga, In, Tl, Fe)(S, Se, Te)₂ and the like.

The doping of the semiconductor to produce a p-type or n-type semiconductor may be achieved via bulk-doping in certain embodiments, although in other embodiments, other doping techniques (such as ion implantation) can be used. Many such doping techniques that can be used will be familiar to those of ordinary skill in the art, including both bulk doping and surface doping techniques. A bulk-doped article (e.g. an article, or a section or region of an article) is an article for which a dopant is incorporated substantially throughout the crystalline lattice of the article, as opposed to an article in which a dopant is only incorporated in particular regions of the crystal lattice at the atomic scale, for example, only on the surface or exterior. For example, some articles are typically doped after the base material is grown, and thus the dopant only extends a finite distance from the surface or exterior into the interior of the crystalline lattice. It should be understood that “bulk-doped” does not define or reflect a concentration or amount of doping in a semiconductor, nor does it necessarily indicate that the doping is uniform. “Heavily doped” and “lightly doped” are terms the meanings of which are clearly understood by those of ordinary skill in the art. In some embodiments, one or more regions comprise a single monolayer of atoms (“delta-doping”). In certain cases, the region may be less than a single monolayer thick (for example, if some of the atoms within the monolayer are absent). As a specific example, the regions may be arranged in a layered structure within the nanoscale wire, and one or more of the regions can be delta-doped or partially delta-doped.

Accordingly, in one set of embodiments, the nanoscale wires may include a heterojunction, e.g., of two regions with dissimilar materials or elements, and/or the same materials or elements but at different ratios or concentrations. The regions of the nanoscale wire may be distinct from each other with minimal cross-contamination, or the composition of the nanoscale wire can vary gradually from one region to the next. The regions may be both longitudinally arranged relative to each other, or radially arranged (e.g., as in a core/shell arrangement) on the nanoscale wire. Each region may be of any size or shape within the wire. The junctions may be, for example, a p/n junction, a p/p junction, an n/n junction, a p/i junction (where i refers to an intrinsic semiconductor), an n/i junction, an i/i junction, or the like. The junction can also be a Schottky junction in some embodiments. The junction may also be, for example, a semiconductor/semiconductor junction, a semiconductor/metal junction, a semiconductor/insulator junction, a metal/metal junction, a metal/insulator junction, an insulator/insulator junction, or the like. The junction may also be a junction of two materials, a doped semiconductor to a doped or an undoped semiconductor, or a junction between regions having different dopant concentrations. The junction can also be a defected region to a perfect single crystal, an amorphous region to a crystal, a crystal to another crystal, an amorphous region to another amorphous region, a defected region to another defected region, an amorphous region to a defected region, or the like. More than two regions may be present, and these regions may have unique compositions or may comprise the same compositions. As one example, a wire can have a first region having a first composition, a second region having a second composition, and a third region having a third composition or the same composition as the first composition. Non-limiting examples of nanoscale wires comprising heterojunctions (including core/shell heterojunctions, longitudinal heterojunctions, etc., as well as combinations thereof) are discussed in U.S. Pat. No. 7,301,199, issued Nov. 27, 2007, entitled “Nanoscale Wires and Related Devices,” by Lieber, et al., incorporated herein by reference in its entirety.

In some embodiments, the nanoscale wire is a bent or a kinked nanoscale wire. A kink is typically a relatively sharp transition or turning between a first substantially straight portion of a wire and a second substantially straight portion of a wire. For example, a nanoscale wire may have 1, 2, 3, 4, or 5 or more kinks. In some cases, the nanoscale wire is formed from a single crystal and/or comprises or consists essentially of a single crystallographic orientation, for example, a <110> crystallographic orientation, a <112> crystallographic orientation, or a <112̅0> crystallographic orientation. It should be noted that the kinked region need not have the same crystallographic orientation as the rest of the semiconductor nanoscale wire. In some embodiments, a kink in the semiconductor nanoscale wire may be at an angle of about 120° or a multiple thereof. The kinks can be intentionally positioned along the nanoscale wire in some cases. For example, a nanoscale wire may be grown from a catalyst particle by exposing the catalyst particle to various gaseous reactants to cause the formation of one or more kinks within the nanoscale wire. Non-limiting examples of kinked nanoscale wires, and suitable techniques for making such wires, are disclosed in International Patent Application No. PCT/US2010/050199, filed Sep. 24, 2010, entitled “Bent Nanowires and Related Probing of Species,” by Tian, et al., published as WO 2011/038228 on Mar. 31, 2011, incorporated herein by reference in its entirety.

In some embodiments, the nanoscale wires used herein are individual or free-standing nanoscale wires. For example, an “individual” or a “free-standing” nanoscale wire may, at some point in its life, not be attached to another article, for example, with another nanoscale wire, or the free-standing nanoscale wire may be in solution. This is in contrast to nanoscale features etched onto the surface of a substrate, e.g., a silicon wafer, in which the nanoscale features are never removed from the surface of the substrate as a free-standing article. This is also in contrast to conductive portions of articles which differ from surrounding material only by having been altered chemically or physically, in situ, i.e., where a portion of a uniform article is made different from its surroundings by selective doping, etching, etc. An “individual” or a “free-standing” nanoscale wire is one that can be (but need not be) removed from the location where it is made, as an individual article, and transported to a different location and combined with different components to make a functional device such as those described herein and those that would be contemplated by those of ordinary skill in the art upon reading this disclosure.

The nanoscale wire, in some embodiments, may be responsive to a property external of the nanoscale wire, e.g., a chemical property, an electrical property, a physical property, etc. Such determination may be qualitative and/or quantitative, and such determinations may also be recorded, e.g., for later use. For example, in one set of embodiments, the nanoscale wire may be responsive to voltage. For instance, the nanoscale wire may exhibits a voltage sensitivity of at least about 5 microsiemens/V; by determining the conductivity of a nanoscale wire, the voltage surrounding the nanoscale wire may thus be determined. In other embodiments, the voltage sensitivity can be at least about 10 microsiemens/V, at least about 30 microsiemens/V, at least about 50 microsiemens/V, or at least about 100 microsiemens/V. Other examples of electrical properties that can be determined include resistance, resistivity, conductance, conductivity, impendence, or the like.

As another example, a nanoscale wire may be responsive to a chemical property of the environment surrounding the nanoscale wire. For example, an electrical property of the nanoscale wire can be affected by a chemical environment surrounding the nanoscale wire, and the electrical property can be thereby determined to determine the chemical environment surrounding the nanoscale wire. As a specific non-limiting example, the nanoscale wires may be sensitive to pH or hydrogen ions. Further non-limiting examples of such nanoscale wires are discussed in U.S. Pat. No. 7,129,554, filed Oct. 31, 2006, entitled “Nanosensors,” by Lieber, et al., incorporated herein by reference in its entirety.

As a non-limiting example, the nanoscale wire may have the ability to bind to an analyte indicative of a chemical property of the environment surrounding the nanoscale wire (e.g., hydrogen ions for pH, or concentration for an analyte of interest), and/or the nanoscale wire may be partially or fully functionalized, i.e. comprising surface functional moieties, to which an analyte is able to bind, thereby causing a determinable property change to the nanoscale wire, e.g., a change to the resistivity or impedance of the nanoscale wire. The binding of the analyte can be specific or non-specific. Functional moieties may include simple groups, selected from the groups including, but not limited to, —OH, —CHO, —COOH, —SO₃H, —CN, —NH₂, —SH, —COSH, —COOR, halide; biomolecular entities including, but not limited to, amino acids, proteins, sugars, DNA, antibodies, antigens, and enzymes; grafted polymer chains with chain length less than the diameter of the nanowire core, selected from a group of polymers including, but not limited to, polyamide, polyester, polyimide, polyacrylic; a shell of material comprising, for example, metals, semiconductors, and insulators, which may be a metallic element, an oxide, an sulfide, a nitride, a selenide, a polymer and a polymer gel. A non-limiting example of a protein is PSA (prostate specific antigen), which can be determined, for example, by modifying the nanoscale wires by binding monoclonal antibodies for PSA (Abl) thereto. See, e.g., U.S. Pat. No. 8,232,584, issued Jul. 31, 2012, entitled “Nanoscale Sensors,” by Lieber, et al., incorporated herein by reference in its entirety.

In some embodiments, a reaction entity may be bound to a surface of the nanoscale wire, and/or positioned in relation to the nanoscale wire such that the analyte can be determined by determining a change in a property of the nanoscale wire. The “determination” may be quantitative and/or qualitative, depending on the application, and in some cases, the determination may also be analyzed, recorded for later use, transmitted, or the like. The term “reaction entity” refers to any entity that can interact with an analyte in such a manner to cause a detectable change in a property (such as an electrical property) of a nanoscale wire. The reaction entity may enhance the interaction between the nanowire and the analyte, or generate a new chemical species that has a higher affinity to the nanowire, or to enrich the analyte around the nanowire. The reaction entity can comprise a binding partner to which the analyte binds. The reaction entity, when a binding partner, can comprise a specific binding partner of the analyte. For example, the reaction entity may be a nucleic acid, an antibody, a sugar, a carbohydrate or a protein. Alternatively, the reaction entity may be a polymer, catalyst, or a quantum dot. A reaction entity that is a catalyst can catalyze a reaction involving the analyte, resulting in a product that causes a detectable change in the nanowire, e.g. via binding to an auxiliary binding partner of the product electrically coupled to the nanowire. Another exemplary reaction entity is a reactant that reacts with the analyte, producing a product that can cause a detectable change in the nanowire. The reaction entity can comprise a shell on the nanowire, e.g. a shell of a polymer that recognizes molecules in, e.g., a gaseous sample, causing a change in conductivity of the polymer which, in turn, causes a detectable change in the nanowire.

Nanoscale wires or surfaces such as those described herein may be used any in any of a variety of devices. Non-limiting examples of such devices include a switch; a diode; a Light-Emitting Diode; a tunnel diode; a Schottky diode; a Bipolar Junction Transistor; a Field Effect Transistor; an inverter; a complimentary inverter; an optical sensor; a sensor for an analyte (e.g., DNA); a memory device; a dynamic memory device; a static memory device; a laser; a logic gate; an AND gate; a NAND gate; an EXCLUSIVE-AND gate; an OR gate; a NOR gate; an EXCLUSIVE-OR gate; a latch; a register; clock circuitry; a logic array; a state machine; a programmable circuit; an amplifier; a transformer; a signal processor; a digital circuit; an analog circuit; an oscillator; a light emission source; a photoluminescent device; an electroluminescent device; a rectifier; a laser; a photodiode; a p-n solar cell.; a phototransistor; a single-electron transistor; a single-photon emitter; a single-photon detector; a spintronic device; an ultra-sharp tip for atomic force microscope; a scanning tunneling microscope; a field-emission device; a photoluminescence tag; a photovoltaic device; a photonic band gap materials; a scanning near field optical microscope tips; and a circuit that has digital and/or analog components. For instance, in one set of embodiments, the device may be a photonic device, a solar cell, or a catalytic scaffold.

As mentioned, selective or anisotropic deposition may occur on other surfaces in other embodiments, in addition to the surfaces of nanoscale wires. Thus, for example, the surface may be a planar surface such as the surface of a wafer. The planar surface may comprise any of the semiconductor materials discussed above in relation to nanoscale wires. For example, the surface may be silicon, germanium, or other elemental semiconductors, such asgermanium, diamond (carbon), tin, selenium, tellurium, boron, or phosphorous. In some cases, the surface may contain more than one element, for example, gallium arsenide, gallium nitride, indium phosphide, cadmium selenide, etc. Still other examples include a Group II-VI material (which includes at least one member from Group II of the Periodic Table and at least one member from Group VI, for example, ZnS, ZnSe, ZnSSe, ZnCdS, CdS, or CdSe), or a Group III-V material (which includes at least one member from Group III and at least one member from Group V, for example GaAs, GaP, GaAsP, InAs, InP, AlGaAs, or InAsP). In some cases, the semiconductor surface is crystalline. The semiconductor may also be responsive to a chemical property of the environment surrounding the semiconductor, e.g., using a reaction entity as discussed above. In some cases, the semiconductor may be used within any of a variety of devices, such as a switch; a diode; a Light-Emitting Diode; a tunnel diode; a Schottky diode; a Bipolar Junction Transistor; a Field Effect Transistor; an inverter; a complimentary inverter; an optical sensor; a sensor for an analyte (e.g., DNA); a memory device; a dynamic memory device; a static memory device; a laser; a logic gate; an AND gate; a NAND gate; an EXCLUSIVE-AND gate; an OR gate; a NOR gate; an EXCLUSIVE-OR gate; a latch; a register; clock circuitry; a logic array; a state machine; a programmable circuit; an amplifier; a transformer; a signal processor; a digital circuit; an analog circuit; an oscillator; a light emission source; a photoluminescent device; an electroluminescent device; a laser; a rectifier; a photodiode; a p-n solar cell.; a phototransistor; a single-electron transistor; a single-photon emitter; a single-photon detector; a spintronic device; an ultra-sharp tip for atomic force microscope; a scanning tunneling microscope; a field-emission device; a photoluminescence tag; a photovoltaic device; a photonic band gap materials; a scanning near field optical microscope tips; and a circuit that has digital and analog components. For instance, in one set of embodiments, the device may be a photonic device, a solar cell, or a catalytic scaffold.

In addition, in some cases, selective deposition techniques such as those described herein can be used, for instance, to form a mask for further deposition onto the nanoscale wire or semiconductor surface, or as a template for further growth or deposition.

The following documents are incorporated herein by reference in their entireties: U.S. Pat. No. 7,211,464, issued May 1, 2007, entitled “Doped Elongated Semiconductors, Growing Such Semiconductors, Devices Including Such Semiconductors, and Fabricating Such Devices,” by Lieber, et al.; U.S. Pat. No. 7,129,554, issued Oct. 31, 2006, entitled “Nanosensors,” by Lieber, et al.; U.S. Pat. No. 7,301,199, issued Nov. 27, 2007, entitled “Nanoscale Wires and Related Devices,” by Lieber, et al.; U.S. patent application Ser. No. 10/588,833, filed Aug. 9, 2006, entitled “Nanostructures Containing Metal-Semiconductor Compounds,” by Lieber, et al., published as U.S. Patent Application Publication No. 2009/0004852 on Jan. 1, 2009; U.S. patent application Ser. No. 11/629,722, filed Dec. 15, 2006, entitled “Nanosensors,” by Wang, et al., published as U.S. Patent Application Publication No. 2007-0264623 on Nov. 15, 2007; U.S. patent application Ser. No. 12/308,207, filed Dec. 9, 2008, entitled “Nanosensors and Related Technologies,” by Lieber, et al.; U.S. Pat. No. 8,232,584, issued Jul. 31, 2012, entitled “Nanoscale Sensors,” by Lieber, et al.; U.S. patent application Ser. No. 12/312,740, filed May 22, 2009, entitled “High-Sensitivity Nanoscale Wire Sensors,” by Lieber, et al., published as U.S. Patent Application Publication No. 2010-0152057 on Jun. 17, 2010; International Patent Application No. PCT/US2010/050199, filed Sep. 24, 2010, entitled “Bent Nanowires and Related Probing of Species,” by Tian, et al., published as WO 2011/038228 on Mar. 31, 2011; International Patent Application No. PCT/US2014/014596, filed Feb. 4, 2014, entitled “Anisotropic Deposition in Nanoscale Wires,” by Lieber, et al.; and U.S. Patent Application Ser. No. 61/989,904, filed May 7, 2014, entitled “Controlled Growth of Nanoscale Wires,” by Lieber, et al.

Also, U.S. Provisional Patent Application Ser. No. 62/011,796, filed Jun. 13, 2014, entitled “Facet-Selective Growth of Nanoscale Wires,” by Lieber, et al. is incorporated herein by reference in its entirety.

The following examples are intended to illustrate certain embodiments of the present invention, but do not exemplify the full scope of the invention.

### Example 1

Heterostructured Si and III-V or II-VI compound semiconductor nanowires are promising materials for next-generation nanoelectronics and nanophotonics. The following non-limiting examples demonstrate selective, epitaxial growth of crystalline films of CdS and InP along the length of specific surface facets of Si nanowires. Crystallographic analysis suggests that the facet-selective growth is facilitated by the formation of an oxide on certain Si wire facets which prevents subsequent film growth. The masking oxide forms selectively on certain facets of the nanowires due to the intrinsic differences in reactivities among the facets rather than through oxide deposition, as in other compound semiconductor/group-IV integration strategies such as selective area epitaxy. This technique, “facet-selective epitaxy,” is general for film growth on faceted Si nano- and microwires and allows laterally confined growth on Si without lithographic patterning, suggesting that it could be used to integration of compound semiconductors on Si.

Integration of Si and III-V or II-VI compound semiconductors is a promising direction for the development of advanced materials for quantum information processing and next generation Si-compatible (opto)electronics. However, mismatches in lattice constants, thermal expansion coefficients, and polarity between Si and compound semiconductors hinder this effort in traditional thin film architectures. Given their confined dimensions and synthetic tunability, nanowires (NWs) have clear advantages in the growth of hybrid structures.

In the following examples, shells of CdS and InP, prototypical II-VI and III-V compounds, are grown on Si NWs with well-defined facets. Previous studies have demonstrated the synthesis of highly crystalline core/shell Si NWs which grow in the [211] direction and whose surfaces are dominated by Si{111}, {113}, and {110} facets. See, e.g., Int. Pat. Apl. No. PCT/US14/14596, filed Feb. 4, 2014, by Lieber, et al., entitled “Anisotropic deposition in nanoscale wires,” incorporated herein by reference in its entirety.

These examples show shell growth of compound semiconductors on Si NWs. Epitaxial growth of CdS and InP preferentially on Si{111} and {110} facets was observed. Experimental evidence for the development of an oxide layer on the Si{113} surface is provided. It is proposed that this oxide prevents subsequent film growth on the Si{113} facets (FIG. 1A), allowing confined film growth on the Si{111} and {110} facets due to the nanoscale dimensions of the Si wires. This is termed facet-selective epitaxy.

Si NWs with well-developed facets and diameters from 200 to 400 nm (FIG. 1B, left) were grown according to previously described procedures. The 2×7 cm² growth substrate with the faceted Si NWs was dipped in buffered HF (BHF) for 20 s to remove surface oxide, rinsed for 5 s in water, and quickly submerged in liquid nitrogen to prevent NW collapse due to capillary action. The frozen growth substrate was quickly transferred to the second zone of a 3-zone furnace and the furnace was evacuated to a base pressure of 50 mTorr. Once at base pressure, the furnace was purged with Ar and H₂ and finally pressurized in H₂ at ˜2.8 Torr with a flow rate of 20 sccm. CdS was evaporated at 710° C. from zone one and deposited on the substrate in zone two at 450-550° C. for 20 minutes.

FIG. 1 shows facet-selective epitaxy. FIG. 1A is a schematic depicting facet-selective growth of a shell material on faceted Si NWs. Selective oxidation of surfaces with different reactivities allows facet-selective growth of shells. FIG. 1B, left, SEM image of a faceted Si NW core before shell growth. Scale bar is 1 micrometer. Top right, SEM images of a Si/CdS heterostructure NW. Scale bar is 2 micrometers. Bottom right, high resolution SEM images of two regions along the length of the NW shown in the upper image. Scale bars are 200 nm. FIG. 1C is EDS line scan profile of Si, Cd, and S along the white arrow denoted in (FIG. 1B, right, bottom). The white arrow is ˜1 micrometer long.

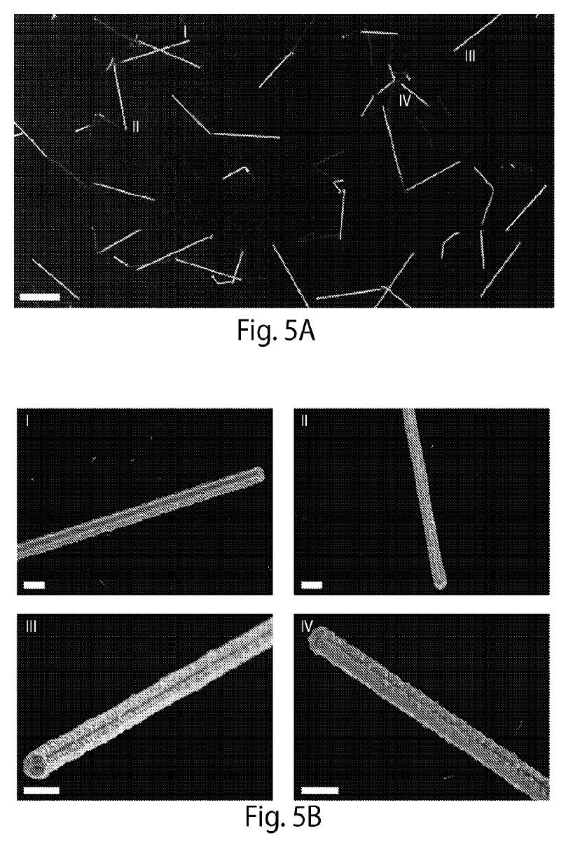

Following CdS deposition, SEM images show facet-selective growth of CdS on faceted Si NWs along the majority of the growth substrate (FIG. 1B, right). Energy-dispersive X-ray spectroscopy (EDS) line scans of the Si/CdS NWs (FIG. 1C) confirmed that CdS growth proceeds selectively on the previously-indexed Si{111} and {110} surface facets, leaving bare Si{113} facets on >95% of NWs (FIG. 5). The CdS film's width was approximately equal to the width of the Si facet upon which it is grown and its thickness is ˜40-80 nm. The CdS was continuous along the entire length of the Si NW's {111} facets.

FIG. 5 shows the yield of facet-selective Si/CdS heterostructure NWs. FIG. 5A is an SEM image of a region of a typical growth substrate in which CdS was grown facet-selectively on every NW in the field of view. Scale bar, 20 micrometers. FIG. 5B shows four high resolution SEM images of facet-selective Si/CdS heterostructure NWs as denoted in the wide-view image above by I, II, III, and IV. Scale bars, 1 micrometer. Facet-selective CdS growth occurred on >95% of faceted Si NWs on the downstream ˜5.5 cm of the growth substrate.

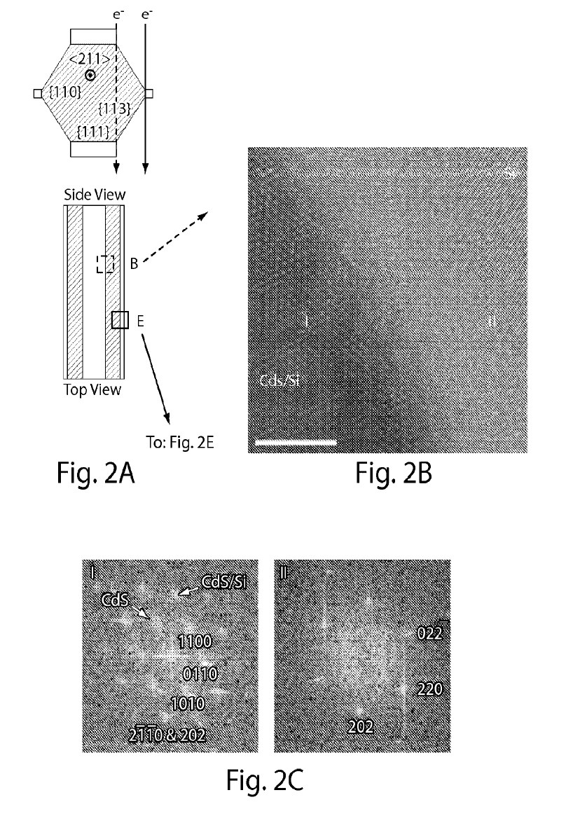

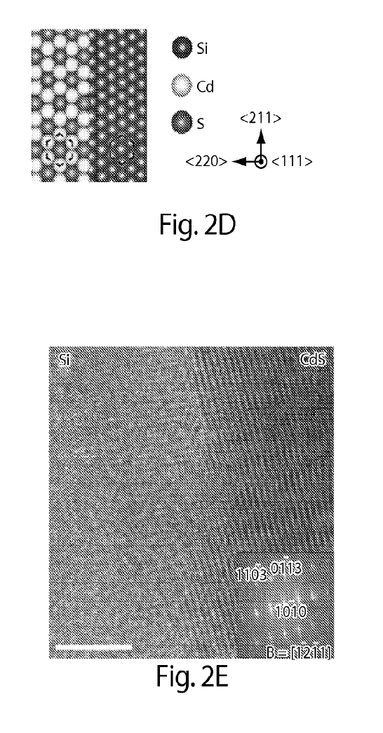

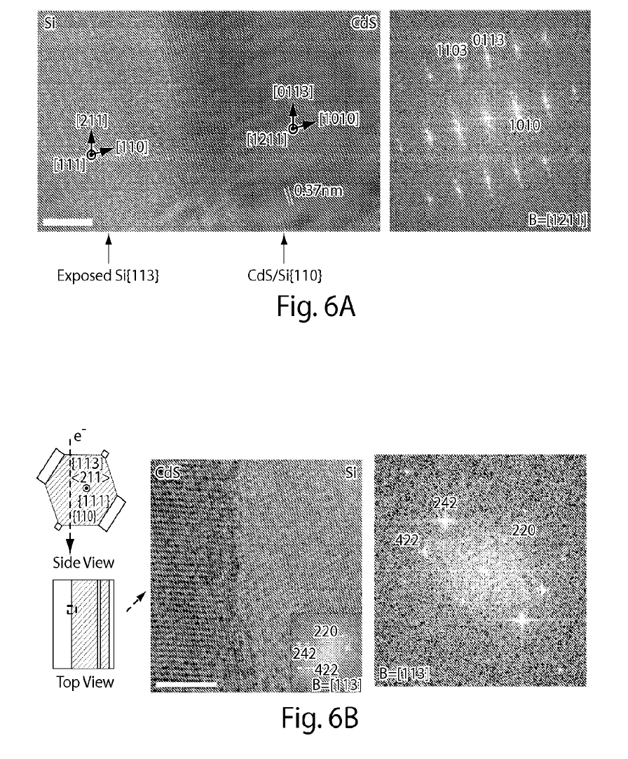

The NWs were imaged in plan-view using aberration-corrected transmission electron microscopy (TEM). As depicted schematically in FIG. 2A, plan-view TEM of facet-selective Si/CdS NWs oriented in the [111] zone axis allowed for inspection of the Si—CdS {111} interface in plan-view (FIG. 2B) and the Si—CdS {110} interface in cross section (FIG. 6A). The TEM image in FIG. 2B showed that, in agreement with SEM images, the CdS deposited selectively on the Si{111} surface facets of the core and did not extend onto the exposed Si{113} surface. A fast Fourier transform (FFT) of the exposed Si region (FIG. 2C, II) yielded a hexagonal pattern, which was indexed to diamond Si[111], consistent with the imaging zone axis and facet orientation. As expected from the imaging geometry, the FFT of the CdS/Si region is a convolution of spots from two layers of CdS and the Si core (FIG. 2C, I). The hexagonal spots attributed to the CdS were indexed to wurtzite CdS[0001] due to the presence of [1100] reflections in the FFT, which would not be present in a FFT of zinc-blende CdS. Orientations of Si and CdS spots with identical symmetries in the FFTs (e.g. [111] and [0001]) were equivalent, suggesting that the orientation of the CdS is determined epitaxially by the underlying Si{111} surface. As shown in FIG. 6A, CdS also grew epitaxially on the Si{110} facet. Finally, imaging the facet-selective Si/CdS NWs in the [113] zone axis (FIG. 6B) confirmed that the bare facet was indeed Si{113} and that neither {113} facet was covered by any detectable CdS film.

FIG. 2 shows plan-view TEM imaging of facet-selective Si/CdS NWs. FIG. 2A shows front- and top-view schematics of plan-view TEM imaging of facet-selective Si/CdS core/shell NWs. Imaging with the long axis of the NWs in the plane of the TEM grid yielded plan-view images of the Si—CdS {111} interface and cross-sectional images of the Si—CdS {110} interface. FIG. 2B is a plan-view TEM image of the Si—CdS {111} interface showing the bare Si{113} facet (right) and CdS grown on the Si{111} facet (left). Scale bar, 4 nm. FIG. 2C shows FFTs from the CdS/Si and bare Si regions as depicted by (I) and (II) in (FIG. 2B), respectively.

FIG. 6 shows TEM characterization of the Si—CdS {110} interface and the Si{113} facets. FIG. 6A shows plan-view TEM images of the Si—CdS {110} interface as depicted schematically in FIG. 2A. Left, TEM image of the Si—CdS {110} interface in cross section. Scale bar, 5 nm. As in FIG. 2, the Si was oriented in the [111] zone axis. Lattice fringes extended continuously from the Si to the CdS and no interfacial layer was observed. An FFT of the CdS was indexed to CdS[1211], indicating that the CdS[1010] and Si[110] directions were parallel. Moreover, CdS lattice fringes measured to be 0.37 nm were in agreement with CdS[1010] planes parallel to the Si{110} facet. Together, these observations confirmed epitaxial growth of CdS on the Si{110} facet. FIG. 6B, left, cross-sectional schematic of the imaging geometry of NWs on the Cu grids in the [113] zone axis. Middle, TEM image of a facet-selective Si/CdS NW in the Si[113] zone axis. Scale bar, 5 nm. Right, FFT from the Si region in the middle TEM image corresponding to the Si[113] zone axis, confirming that the Si{113} facets were devoid of any CdS film.

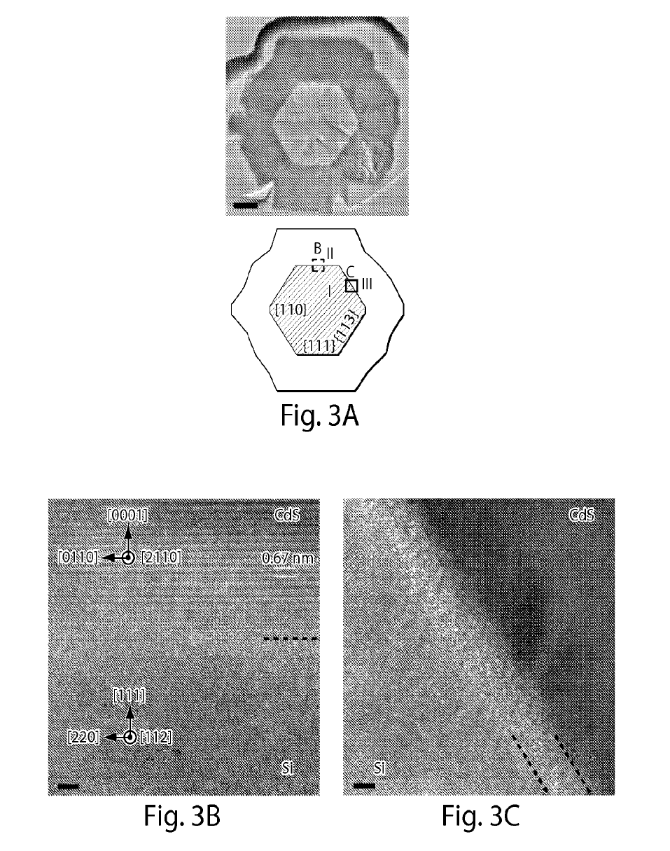

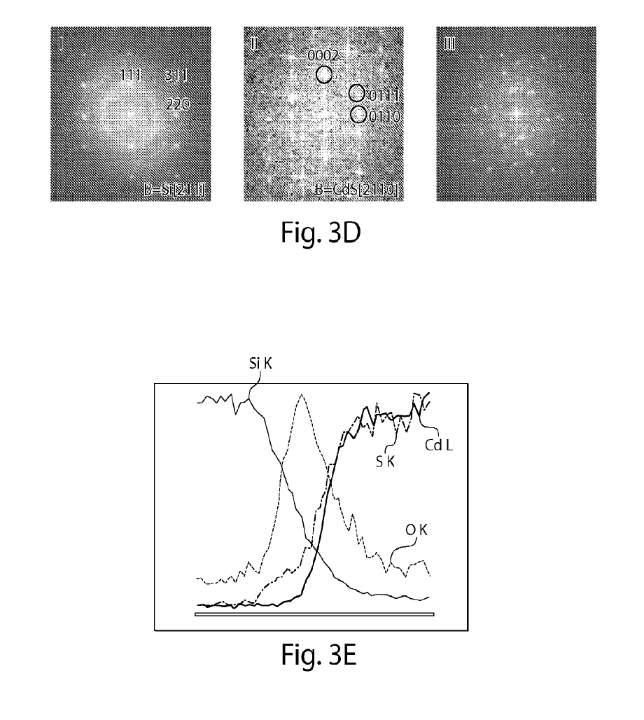

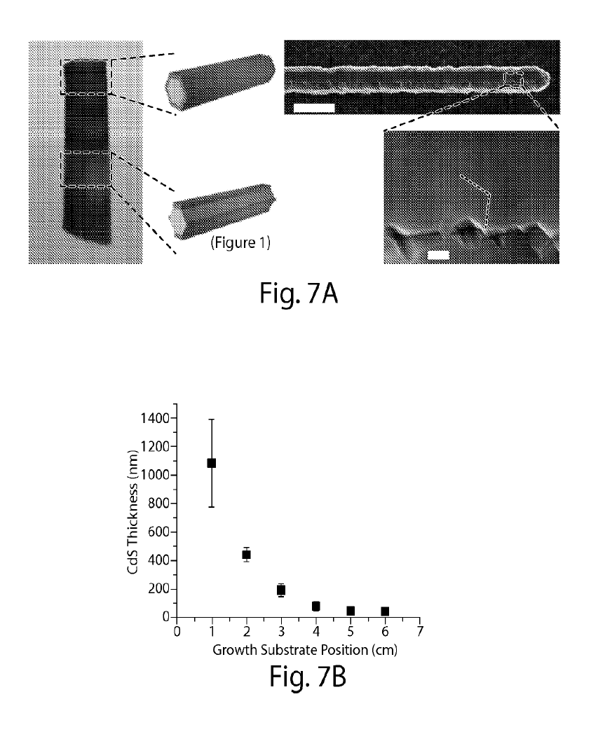

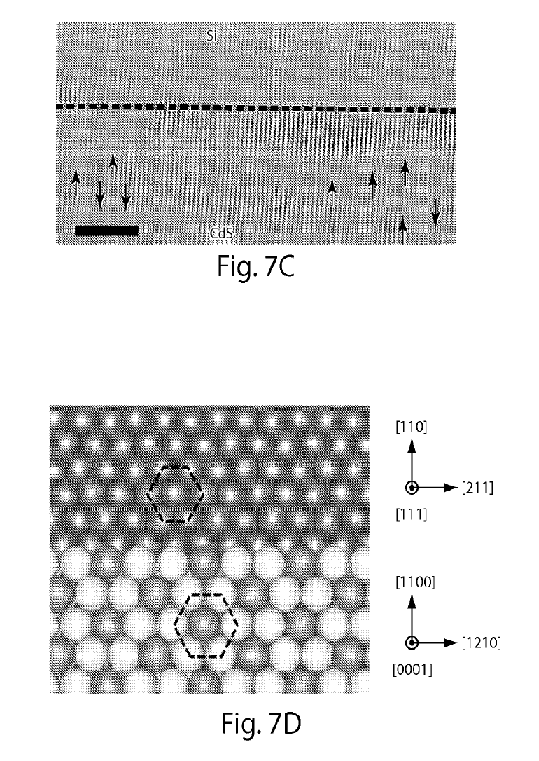

In contrast to the facet-selective Si/CdS NWs observed downstream, SEM images of the upstream ˜1.5 cm of the growth substrate revealed conformally coated NWs with diameters of ˜1-2 micrometers (FIG. 7A). In all positions on the growth substrate, SEM images indicated that the surface of the CdS film grown on the Si{111} facet was smooth and showed hexagonal surface steps (FIG. 7A, right). The difference in morphology between upstream and downstream NWs may be attributed to the decreasing amount of CdS deposited along the length of the growth substrate (FIG. 7B). To better probe the mechanism of facet selective growth, TEM was used to image a cross section of one of these conformal Si/CdS core/shell NWs found upstream on the growth substrate. The cross section was created by focused ion beam (FIB) milling and subsequent lift out via micromanipulator. A low magnification TEM view and schematic of the cross section (FIG. 3A) showed a Si core with smooth surface facets and low z-contrast, a CdS shell with higher z-contrast, and an amorphous sacrificial carbon layer deposited to protect the sample from FIB damage. In agreement with FIG. 7A, smooth (rough) CdS surfaces which were parallel to the Si{111} (Si{113}) surfaces were observed.

The Si—CdS {111} interface is shown in FIG. 3B. The dashed line indicates the transition from Si to CdS. Continuous lattice fringes were observed from the Si to the CdS, and no interfacial layer between the core and shell, accordant with epitaxial growth of CdS on Si{111} as discussed previously. FFTs of the Si (FIG. 3D, I) and CdS grown from the Si{111} facet (FIG. 3D, II) were indexed to Si[211] and CdS[2110]. Both FFTs and their respective crystal directions had identical symmetry, consistent with the epitaxial relationship between the Si and CdS. The CdS[2110] FFT confirmed CdS growth direction perpendicular to the NW Si{111} facet to be [0001], in agreement with 0.67 nm periodicity observed for the CdS lattice fringes parallel to the Si—CdS {111} interface. Based on a Fourier filtered image of this interface, misfit dislocations in the CdS film were observed ˜4 nm away from the Si—CdS interface (FIG. 7C) in agreement with the critical thickness approximation for ˜7% strain between Si{111} and CdS{0001}.

A model of wurtzite CdS growing epitaxially on a Si{111} surface was constructed (FIG. 7D). As in their corresponding FFTs, both Si{111} and CdS{0001} had hexagonal symmetry, consistent with the growth directions observed in the TEM images and hexagonal CdS surface steps observed in high-resolution SEM images (FIG. 7A). This appears similar to polytypism in the same nanocrystal in which zinc-blende/cubic {111} and hexagonal {0001} faces meet at a coherent interface between hexagonal and cubic phases.

Imaging the Si—CdS {113} interface revealed a ˜3 nm layer which interrupts the Si and CdS lattice fringes as denoted by the dashed lines in the TEM image in FIG. 3C. The absence of structural features and fringes suggested that this interfacial layer was amorphous. The FFT from the CdS grown on the Si{113} surface (FIG. 3D, III) indicated that the CdS in this region was randomly oriented and polycrystalline, consistent with growth of CdS on an amorphous film and the rough surface observed parallel to the Si{113} surfaces. A scanning TEM (STEM) EDS line scan of the interfacial layer indicated that the amorphous layer is an oxide (FIG. 3E).

FIG. 3 shows cross-sectional TEM imaging of a Si/CdS core/conformal shell heterostructure NW. FIG. 3A, top, TEM image of a cross section from a Si/CdS NW at the upstream end of the growth substrate. The cross section was surrounded by an amorphous carbon layer to protect from Ga FIB damage; the notch in the bottom right of the cross section was due to Ga FIB damage. Scale bar, 200 nm. Bottom, schematic depicting the geometry of the cross-section. B and C denote areas where the Si—CdS {111} and {113} interfaces were imaged at high magnification and presented in FIG. 3B and FIG. 3C. I, II, and III refer to the locations from which the FFTs in FIG. 3D were derived. FIGS. 3B and 3C, aberration-corrected TEM images of the Si—CdS (FIG. 3B) {111} and (FIG. 3C) {113} interface. Scale bars, 2 nm. FIG. 3D FFTs of (I) Si, (II) CdS grown on the Si{111} facet, and (III) CdS grown on the Si{113} facet. FIG. 3E shows EDS line scan profile of Si, 0, Cd, and S along the Si—CdS {113} interface. The elemental intensity profiles are overlaid on a STEM image of the interface. The white line is ˜17 nm long.

FIG. 7 shows characterization of Si/CdS NWs from the upstream portion of the growth substrate. FIG. 7A, left, a camera image of a growth substrate showing colored bands corresponding to interference from the decreasing thickness of the CdS film down the length of the substrate. The growth substrate was 2 cm wide. Right, position-dependent morphology of Si/CdS heterostructure nanowires. Upstream (upper box and SEM images), the CdS grew conformally on the faceted Si core. The CdS showed well-developed facets parallel to the Si{111} surfaces (top) and had hexagonally symmetric surface features, as shown in the enlarged image of the region denoted by the dashed right box. Dashed white lines are guides to the eye showing the hexagonal CdS surface steps. Scale bars, 4 micrometers (top) and 200 nm (bottom). Downstream (lower box), CdS grew facet-selectively on the Si core, as shown in FIG. 1. FIG. 7B, CdS film thickness, measured by SEM, as a function of position on the growth substrate. Conformal growth was observed ˜0-1.5 cm from the top of the growth substrate; facet-selective growth was observed further downstream. FIG. 7C shows a Fourier filtered TEM image of the Si—CdS {111} interface showing defects (arrows) ˜4 nm from the interface, in agreement with the critical thickness approximation. FIG. 7D shows a molecular model depicting the Si—CdS {111}-{0001} interface. Si{111} and CdS {0001} both had hexagonal symmetry, allowing an interface between cubic and hexagonal phases in the same polytypic nanocrystal.

### Example 2

This example illustrates a proposed mechanism for facet-selective growth of CdS on the Si{111} and {110} facets. The above results suggest that an amorphous oxide layer prevents CdS growth on the Si{113} surface in the downstream region of the growth substrate. Though the Si{113} oxide clearly forms on the upstream NWs as well (FIG. 3C), it is believed that the CdS shell develops conformally upstream because growth occurs in the burial regime (consistent with the higher flux upstream, FIG. 7B), meaning that CdS adatoms were buried under the incoming flux before they have time to diffuse or desorb. However, under the lower CdS flux downstream, it is believed that CdS adatoms have time to diffuse or desorb from the {113} oxide, yielding facet-selective CdS growth (FIG. 1A). This hypothesis implies that the Si{113} surface forms an oxide during the early stages of the growth, whereas the Si{111} surface remains oxide-free after the BHF etch.

Previous literature reports that the sticking coefficient, S_{c}, of water is two orders of magnitude higher for Si{113} (S_{c H2O Si(113)}˜0.58) than for Si{111} (S_{c H2O Si(111)}˜10⁻²). Adsorbed water may split to desorb H and the remaining 0 may be incorporated into the Si surface as an oxide at 350-550° C. Given the nature of the apparatus, residual water from the CdS precursor and/or the BHF etch may remain in the furnace before growth, contributing to the growth of this oxide on the Si{113} surface.

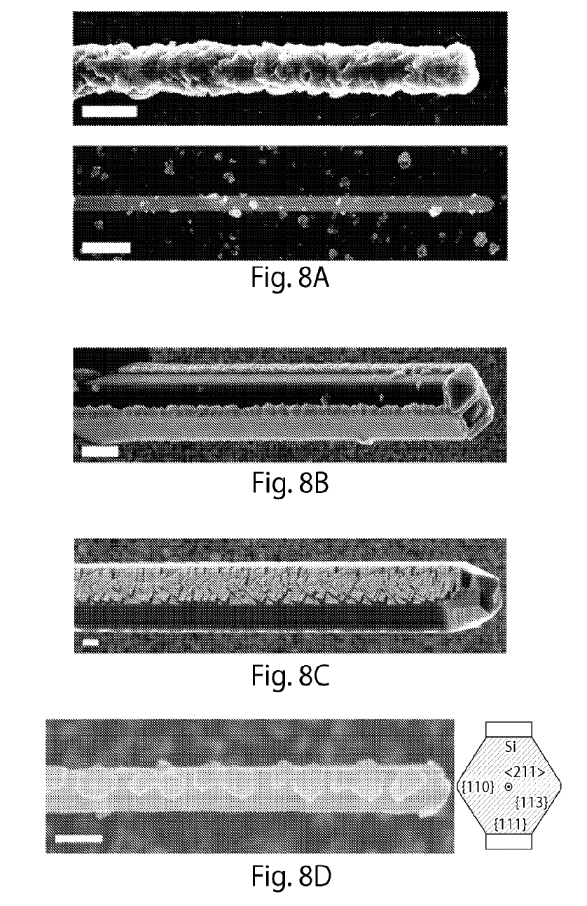

One implication of this model is that the S_{c} of CdS on oxide is lower than that on Si. To test this, CdS was grown on faceted Si NWs without etching away the Si NWs' native oxide before CdS deposition (FIG. 8A). Upstream, CdS films were conformal on the Si NWs but appeared rough and lacked the well-developed facets observed when the Si NWs' native oxide was removed as in FIGS. 1 and 7. Downstream, no continuous CdS was deposited on any facets of the NWs with native oxide, in contrast to the facet-selective heterostructure NWs observed at the equivalent growth substrate positions when the native oxide was removed prior to CdS shell growth (FIG. 1B). This control experiment confirmed that under low flux conditions, the sticking coefficient of CdS on oxide was low and that under high flux conditions, the oxide was buried by the film.

Next, the role of the size of the NW and the freeze dry process on CdS growth was tested by growing Si microwires with diameters of ˜3 micrometers and etching in BHF without the freeze dry process described above. Again, facet-selective CdS growth was observed on the Si{111} and {110} facets (FIG. 8B), suggesting that neither the size of the Si wire's surface facets nor the freeze dry process significantly impact facet-selective CdS growth on Si wires.

FIG. 8 shows the results of control growth experiments. FIG. 8A shows upstream (top) and downstream (bottom) Si/CdS heterostructure NWs grown without a BHF etch prior to CdS deposition. Upstream, the CdS deposited conformally on the NWs but lacked the well-developed surface facet seen in the NWs grown with BHF etch prior to CdS deposition as in FIG. 5; downstream, no continuous CdS deposited on the Si NWs, in contrast to those shown in FIG. 1. Scale bars, 1 micrometer. FIG. 8B is an SEM image of a Si/CdS heterostructure microwire. Larger (˜3 micrometer diameter) Si wire cores were grown to avoid capillary-action-driven wire collapse to the growth substrate upon drying the NWs in a stream of nitrogen after a BHF etch. CdS deposited on the Si{111} facets but did not deposit on the Si{113} facets, suggesting that neither the width of the surface facets nor the freeze dry process had a significant effect on the facet-selective growth of CdS. Scale bar, 2 micrometers.

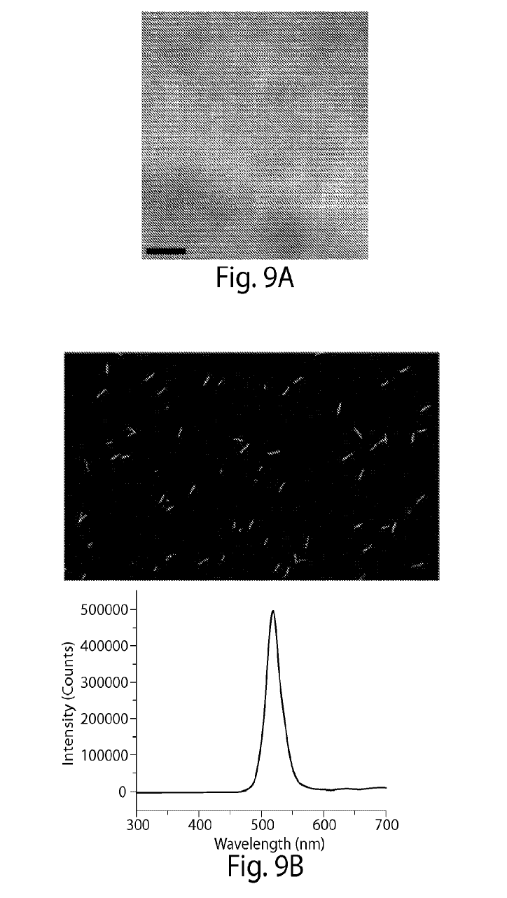

Since an oxide prevents growth of CdS on the Si{113} facets, this is termed facet-selective epitaxy. However, we note that the novelty of our findings stems from the natural formation of an oxide due to the intrinsic difference in reactivity of the NW surfaces rather than lithographic patterning and subsequent oxide deposition, as in SAE. One advantage of facet-selective epitaxy is that the growth of the CdS is laterally confined to the approximate width of the Si{111} facet upon which it grows; this width is tunable by adjusting the size of the Si core/shell wires, as demonstrated by CdS growth on both nano- (FIG. 1) and microwires (FIG. 8B). Moreover, despite the aforementioned defects at the Si—CdS {111} interface (FIG. 7C), the surface of the CdS was relaxed and had low defect density (FIG. 9A) compared to the interfacial region, suggesting that defects from the interface are able to relax before the surface of the CdS.

### Example 3

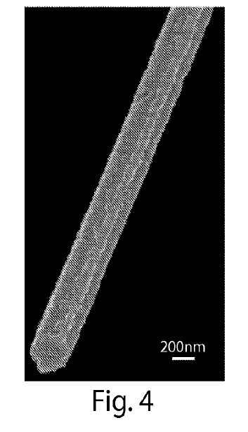

Facet-selective epitaxy relies on properties of the Si NW facets rather than on the nature of the growing film itself. Thus, selective area epitaxy should be general to other materials. This generality was demonstrated in this example by growing InP on faceted Si NWs. InP was evaporated similarly to the CdS in the 3-zone furnace and the Si NWs were prepared by the same BHF etch/freeze dry process. SEM images and EDS profiles in FIG. 4 confirmed that InP grew selectively on the {111} and {110} facets of the Si core but that the {113} facet remained exposed. Moreover, considering that facet-selective epitaxy was not selective to film materials or to the size of the NWs, it was expected that this technique was not specific to NWs, and thus facet-selective epitaxy could be realized on a Si wafer or other geometry whose surface features a combination of {111} and {113} facets. FIG. 4 shows the generality of facet-selective epitaxy. FIG. 4A shows an SEM image of a facet-selective Si/InP core/shell heterostructure NW. Scale bar, 200 nm.

Facet-selective epitaxy of CdS and InP was observed on the {111} and {110} facets of Si NWs. Facet-selectivity may be attributed to an oxide on the Si{113} surfaces which inhibits shell growth. Since the fact that the film is relaxed at its surface, it is believed that synthesis of Si NWs capped by well-defined surfaces could serve as a unique platform in which to integrate compound semiconductors with group-IV materials without an additional patterning step. Such hybrid structures are promising for quantum information processing and optoelectronics. Indeed, the Si/CdS heterostructure NWs display strong band-edge photoluminescence around 2.4 eV (FIG. 9B). Moreover, it is believed that the relaxed and smooth CdS surface could serve as an intermediate buffer layer for epitaxial growth of films which would otherwise have a significant lattice mismatch with Si and that compound semiconductor growth on narrow Si{111} facets might allow for strain relaxation at the edges of the shell island to yield defect-free interfaces as has been observed for small (<30 nm) diameter III-V NWs grown epitaxially on Si{111}.

FIG. 9 shows characterization of the Si/CdS heterostructure NWs for (opto)electronics applications. FIG. 9A is a TEM image recorded of the CdS in cross section near the surface facet parallel to the Si{111} surface. The CdS near the surface of the NW was close to defect-free. Scale bar, 5 nm. FIG. 8B shows optical properties of the Si/CdS heterostructure NWs. Top, photoluminescence image of facet-selective Si/CdS heterostructure NWs randomly dispersed on a quartz substrate showing strong green emission from every NW. Bottom, room temperature photoluminescence spectrum of a single Si/CdS NW on a quartz slide showing band-edge emission at ˜514 nm (2.4 eV). Excitation wavelength and power were 405 nm and ˜1 mW, respectively.

### Example 4

The following are additional materials and methods used in the above examples. Faceted Si nanowires (NWs) with diameters from 200 to 400 nm were grown according to a established procedures. The growth substrate with the faceted Si NWs was dipped in buffered HF (BHF) for 20 s to remove surface oxide, rinsed for 5 s in deionized water, and quickly submerged in liquid nitrogen to prevent the NWs from collapsing via capillary action when the remaining water on the substrate is evaporated in vacuum. The frozen growth substrate was quickly transferred to the second zone of a 3-zone furnace and the furnace was evacuated to a base pressure of 50 mTorr. Once at base pressure, the furnace was purged three times each with Ar and H₂ and finally pressurized in H₂ at ˜2.8 Torr with a flow rate of 20 sccm.

The 3-zone furnace was equipped with a quartz boat transfer rod which was fed into the furnace via a feedthrough which was differentially pumped to minimize the amount of air which enters the furnace during quartz boat transfer. Prior to growth and pumping down, the quartz transfer boat was loaded with either CdS powder (Alfa Aesar, 99.999%) or milled InP (Alfa Aesar, 99.9999%). Once the temperature of zone one stabilized at 670-710° C., the quartz rod was pushed through the feedthrough such that the precursor was in the center of zone one. Films were grown on the Si NWs in zone two at 450-550° C. for 5-20 minutes.

Nanowires were imaged directly on the growth substrate using a Zeiss Ultra Plus or a Supra55VP field emission scanning electron microscope (SEM). Energy dispersive X-ray spectroscopy (EDS) line scans were acquired in the Supra55VP SEM at 10 kV accelerating voltage and 800 ms dwell time using commercial EDAX Genesis software. For plan-view TEM imaging, NWs were shear transferred from the growth substrate to amorphous-carbon coated copper TEM grids (Ted Pella). The cross-section of an upstream NW was prepared via deposition of a protective carbon layer and subsequent lift-out in a Zeiss NVision 40 dual-beam SEM/focused ion beam (FIB) equipped with an Omniprobe micromanipulator. Both the plan-view NWs and the cross section were characterized using an aberration-corrected Zeiss Libra MC TEM operating at 200 keV. STEM/EDS characterization was completed using an aberration-corrected Hitachi HD-2700 STEM operating at 200 keV.

Optical characterization at room temperature utilized a home-built epifluorescence microscope. A continuous-wave 405 nm diode laser (LaserGlow Technologies) was collimated and focused to a ˜1 micrometer spot with a 40× objective lens (NA=0.75; Olympus America Inc.). The laser and luminescence were routed through a 405 nm dichroic and subsequently through two 450 nm long pass filters to a spectrometer with a 300 lines mm-1 grating and spectral resolution ˜1 nm and charge coupled device (Princeton Instruments). Photoluminescence images were recorded at room temperature using a scanning confocal microscope (FluoView FV1000; Olympus America Inc.) with a 473 nm excitation laser and a 490-540 nm band pass filter to pass photoluminescence and block the laser light.

### Example 5

This example is generally directed to facet-selective epitaxy of compound semiconductors on faceted silicon nanowires.

Integration of compound semiconductors with silicon (Si) has been a long standing goal for the semiconductor industry, as direct band gap compound semiconductors offer, for example, attractive photonic properties not possible with Si devices. However, mismatches in lattice constant, thermal expansion coefficient, and polarity between Si and compound semiconductors render growth of epitaxial heterostructures challenging. Nanowires (NWs) are a promising platform for the integration of Si and compound semiconductors since their limited surface area can alleviate such material mismatch issues. This example demonstrates facet-selective growth of cadmium sulfide (CdS) on Si NWs. Aberration-corrected transmission electron microscopy analysis shows that crystalline CdS was grown epitaxially on the {111} and {110} surface facets of the Si NWs but that the Si{113} facets remained bare. Further analysis of CdS on Si NWs grown at higher deposition rates to yield a conformal shell revealed a thin oxide layer on the Si{113} facet. This observation and control experiments suggest that facet-selective growth was facilitated by the formation of an oxide which prevented subsequent shell growth on the Si{113} NW facets. Further studies of facet-selective epitaxy growth of CdS shells on micro-to-mesoscale wires, which allows tuning of the lateral width of the compound semiconductor layer without lithographic patterning, and InP shell growth on Si NWs demonstrated the generality of this growth technique. In addition, photoluminescence imaging and spectroscopy showed that the epitaxial shells displayed strong and clean band edge emission, confirming their high photonic quality, and thus suggesting that facet-selective epitaxy on NW substrates represents a promising route to integration of compound semiconductors on Si.

Integration of Si and compound III-V or II-VI semiconductors is an attractive goal since such heterostructures could marry the attractive photonic properties of direct band gap compound semiconductors with Si devices. However, mismatches in lattice constant, thermal expansion coefficient, and polarity between Si and compound semiconductors render growth of epitaxial heterostructures challenging. NWs represent a promising platform for the integration of Si and compound semiconductors since their small cross-sectional footprint and surface area can alleviate issues created by lattice, thermal, and polarity mismatches.

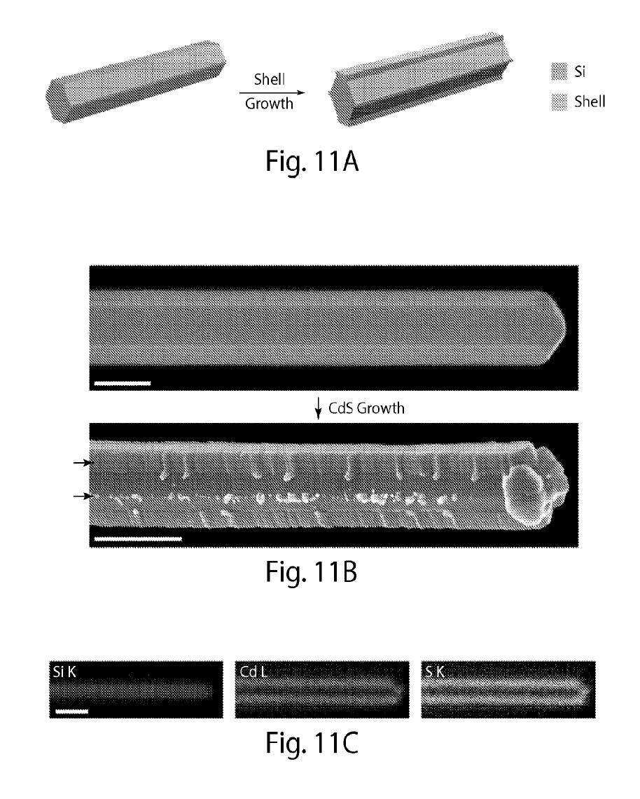

Conceptually, facet-selective growth provides techniques by which to reduce the interfacial area of mismatched materials, since the growing layer is confined to the width of the facet on which it is deposited. The synthesis of crystalline core/shell Si NWs which grow in the <211> direction and whose surfaces are terminated by well-defined Si{111}, {113}, and {110} facets has been discussed. These examples investigate the growth of CdS and InP shells, which are prototypical II-VI and III-V compounds, on Si NWs with well-defined facets, as shown schematically in FIG. 11A.

Si NWs with well-developed facets and diameters from 200 to 400 nm (FIG. 11B, left) were grown as discussed herein (see below). The growth substrate with the faceted Si NWs was dipped in aqueous buffered hydrofluoric acid (BHF) for 20 s to remove surface oxide, rinsed for 5 s in deionized water, and then submerged in liquid nitrogen to prevent collapse of the NWs via capillary forces during liquid water evaporation. The frozen growth substrate was quickly transferred to the second zone of a 3-zone furnace and the tube was evacuated to a base pressure of 50 mTorr; during this process, the ice sublimed. Once at base pressure, the furnace was purged three times each with Ar and H₂ and the pressure was set at ˜2.8 Torr with a flow rate of 20 sccm H₂. CdS was evaporated at 670-710° C. from zone 1 and deposited on the substrate in zone 2 at 450-550° C. for 5-40 minutes.

Scanning electron microscope (SEM) images of the Si NWs before and following CdS growth reveal several features (FIG. 11B). First, before growth, the Si NWs exhibited well-faceted structures. Second, following CdS growth, the SEM image shows CdS on distinct facets of the Si NWs. The image shows that (i) the CdS formed a continuous stripe along the upper/lower facets and islands along the much narrower middle facet, and (ii) the intervening facets were free of deposited CdS. This suggests that the continuous CdS growth occurred on Si NW {111} facets while the islands formed on {110} facets. Indeed, elemental mapping via energy-dispersive X-ray spectroscopy (EDS) in a scanning transmission electron microscope (STEM; FIG. 11C) showed the spatial distributions of Si, Cd, and S from a Si NW oriented in the Si<110> zone axis. The elemental distribution matched the geometry shown in the schematic and the SEM images of FIGS. 11A and 11B, and moreover, confirmed that the CdS shells were primarily localized on the Si{111} facets.

FIG. 11 shows facet-selective epitaxy on Si NWs. FIG. 11A shows a schematic depicting facet-selective growth of a shell material on faceted Si NWs. FIG. 11B, top, is an SEM image of a faceted Si NW before CdS growth. The bottom is an SEM image of a Si/CdS heterostructure NW following CdS deposition. The upper and lower arrows indicate CdS on Si{111} and {110} facets, respectively. Scale bars, 500 nm. FIG. 11C shows STEM EDS elemental mapping of Si (left), Cd (misdle), and S (right) of a NW oriented in the Si<110> zone axis. Scale bar, 500 nm.

### Example 6

To further characterize the facet-selective Si/CdS NW structure, we used plan-view aberration-corrected TEM (FIGS. 2 and 6). As depicted schematically in FIG. 2A, (plan-view TEM) facet-selective Si/CdS NWs oriented in the Si[111] zone axis allows for inspection of the Si—CdS{111} interface in plan-view and the Si—CdS{110} interface in cross-section. The TEM image of the Si—CdS{111} interface in plan-view (FIG. 2B) shows a high contrast area on the left, due to CdS on the Si, while the lower contrast area on the right corresponds to exposed Si. The clear boundary between the Si and CdS in FIG. 2B confirms that, in agreement with FIG. 11, CdS deposited selectively on the Si{111} surface facets of the Si NW and did not extend onto the Si{113} surface. In addition, a fast Fourier transform (FFT) of the exposed Si region (FIG. 2C, II) yielded a hexagonal pattern that can be indexed to Si<111>, and was consistent with the imaging zone axis and facet orientation. The FFT of the CdS/Si region was a convolution of spots from two layers of CdS and the Si NW (FIG. 2C, I), as expected from the imaging geometry. Importantly, it was possible to index the distinct CdS hexagonal spots to wurtzite CdS<0001> due to the presence of {1100} reflections in the FFT, which would not be present in a FFT of zinc-blende CdS. The orientations of Si and CdS spots with identical symmetries in the FFTs were equivalent, strongly suggesting that the orientation of the CdS was determined by epitaxy with the underlying Si{111} surface.

A crystal structure model based on the TEM image and FFT analyses of the Si<111>/CdS<0001> zone axis (FIG. 2D) depicted wurtzite phase CdS (left: S and Cd) growing epitaxially on a Si{111} surface adjacent to an exposed Si{113} facet (right). As in their corresponding FFTs, both Si{111} and CdS{0001} had hexagonal symmetry, highlighted by the dashed hexagon in the model. This is believed to be the first report of clearly characterized heteroepitaxial polytypism between a NW core with cubic symmetry and a NW shell with hexagonal symmetry.

Additional plan-view TEM imaging of the Si—CdS interface at the Si{110} facet (FIG. 2E and schematic FIG. 2A) shows that lattice fringes extended continuously from Si to the CdS, and moreover, there was no evidence for an interfacial layer. The FFT from this image (FIG. 2E, inset) was indexed to CdS <1211>, which indicated that the CdS<1010> and Si<110> directions were parallel. Moreover, CdS lattice fringes, with 0.37 nm spacing, were in agreement with CdS{1010} planes parallel to the Si{110} facet. Together, these observations confirmed that CdS growth on the Si{110} facets was also epitaxial.

The facet-selective Si/CdS NWs was tilted into the Si<113> zone axis (schematic, FIG. 6B) to allow for plan-view imaging of the Si{113} facets. FIG. 6B shows a TEM image of a Si{113} facet, where high contrast CdS grown on the adjacent Si{111} facet is observed on the left and the low contrast Si{113} facet is seen on the right. An FFT (FIG. 6B, middle, inset) from the Si region confirmed the zone axis as Si<113>. TEM imaging in the Si<113> zone axis did not yield any detectable CdS on the Si{113} facets.

FIG. 2A shows side- and top-view schematics of plan-view TEM imaging of facet-selective Si/CdS NWs oriented in the Si<111> zone axis. FIG. 2 B is a plan-view TEM image of the Si—CdS {111} interface showing the Si{113} facet (right) and CdS grown on the Si{111} facet (left). Scale bar, 4 nm. FIG. 2C shows FFTs from the CdS/Si and bare Si regions as depicted by (I) and (II) in FIG. 2B, respectively. FIG. 2D shows a crystal structure model oriented in the Si<111> zone axis, showing CdS epitaxially grown on a Si{111} facet next to a bare Si{113} facet. Crystal directions are indicated on the right. FIG. 2E is a plan-view TEM image of the Si—CdS{110} interface showing the Si{113} facet (left) and CdS grown on the Si{110} facet (right). Scale bar, 4 nm. Inset, FFT from the CdS in the TEM image.

FIG. 6B shows side- and top-view schematics of plan-view TEM imaging of facet-selective Si/CdS NWs oriented in the Si<113> zone axis, and TEM images of a facet-selective Si/CdS NW in the Si<113> zone axis. Scale bar, 4 nm. Inset in middle, FFT from the Si in the TEM image.

### Example 7

Facet-selective CdS growth on Si NWs along the majority of the growth substrate was observed. However, Si NWs closest to the upstream CdS source where the Cd/S reactant concentration is highest (FIG. 3A) showed conformal CdS shells on the SiNW cores. To better probe the mechanism of facet-selective growth, the conformal core/shell Si/CdS NWs with cross-sectional TEM imaging was characterized (see below). A low magnification TEM view and schematic of the cross-section (FIG. 3A, top and bottom) showed the low contrast Si NW core with smooth surface facets, the concentric high contrast CdS shell, and an amorphous sacrificial carbon layer, which was deposited for sample preparation. The notch in the bottom right of the cross-section was caused by Ga FIB damage during cross-section thinning. The conformal Si/CdS NW displayed smooth CdS surfaces parallel to the Si{111} facets but rough CdS surfaces parallel to the Si{113} facets, as shown schematically in the bottom of FIG. 3A.

In addition, higher resolution TEM images of the Si—CdS{111} interface (FIG. 3B) showed continuous lattice fringes from the Si to the CdS and no interfacial layer between the Si NW and CdS. FFTs of the Si (FIG. 3D, I) and CdS (FIG. 3D, II) were indexed to Si<211> and CdS<2110>, respectively. Both FFTs and their respective crystal directions had identical symmetry. The Si[211] crystal direction matched the previously reported growth direction of the SiNWs. Moreover, the periodically spaced 0.67 nm CdS lattice fringes parallel to the Si—CdS{111} interface showed that the CdS growth direction normal to the Si{111} facet was <0001>. Taken together, this confirms the epitaxial relationship between the Si and CdS on the Si{111} interface, consistent with the plan-view TEM analysis of the facet-selective Si/CdS NWs in FIG. 2.

Interestingly, TEM images of the Si—CdS{113} interface (FIG. 3C) revealed a ˜3 nm layer which interrupted the Si (left) and CdS (right) lattice fringes and which was devoid of structural features and fringes. An FFT recorded from the CdS (FIG. 3D, III) revealed randomly angled spot patterns, indicating that the CdS in this region is polycrystalline, in agreement with the rough CdS shell surface observed parallel to the Si{113} surfaces. Together, this indicates that the interfacial layer was amorphous. An aberration-corrected STEM EDS line scan (FIG. 3E) revealed the presence of oxygen, consistent with amorphous silicon oxide in the interfacial layer separating Si and CdS.

Based on the above data, it is believed that facet-selective growth of CdS on the Si{111} and {110} facets can be attributed at least in part to a passivating amorphous silicon oxide layer on the Si{113} facets. Without wishing to be bound by any theory, although oxide was removed from the Si NWs immediately prior to placement in the CdS growth reactor, the sticking coefficient of water is two orders of magnitude higher for Si{113} than for Si{111} and that adsorbed water may decompose to form silicon surface oxide at temperatures comparable to the CdS growth. Given the base pressure of the growth apparatus, it is possible that residual water/oxygen may lead to oxide formation on Si{113} prior to deposition of CdS. Since there was no chemical difference between the Si NWs upstream and downstream (relative to the CdS reactant source), the Si{113} oxide formed on NWs in both positions. However, the differences in CdS flux between upstream and downstream locations resulted in facet selectivity. Upstream, CdS shells grew conformally because the higher reactant flux precluded sufficient time for diffusion and/or desorption. This suggestion is consistent with the ˜1-2 micrometer CdS shells on upstream Si NWs (FIG. 3A). In contrast, the lower CdS flux at the downstream position allowed for diffusion and/or desorption from the {113} oxide before incorporation into the shell, thereby yielding facet-selective CdS growth.

FIG. 3 shows cross-sectional TEM imaging of a conformal Si/CdS core/shell NW. FIG. 3A, top, TEM image of a cross-section from the conformal core/shell Si/CdS NW. Scale bar, 200 nm. Bottom, schematic depicting the geometry of the cross-section. B and C denote areas where the Si—CdS{111} and {113} interfaces were imaged at high magnification and presented in FIG. 3B and FIG. 3C. I, II, and III refer to the FFT locations in FIG. 3D. FIGS. 3B and 3C are aberration-corrected TEM images of the Si—CdS (B) {111} and (C) {113} interfaces. Scale bars, 2 nm. Dashed lines denote (FIG. 3B) the interface between Si and CdS and (FIG. 3C) an interfacial layer between the Si and CdS. FIG. 3D shows FFTs derived from (I) Si, (II) CdS grown on the Si{111} facet, and (III) CdS grown on the Si{113} facet. FIG. 3E shows a STEM EDS line scan profile of Si, 0, Cd, and S through the Si—CdS {113} interface. The elemental intensity profiles are overlaid on a STEM image of the interface. The white line is ˜17 nm long.

### Example 8

To better understand the role of oxide in the growth of CdS on Si NWs, in this example, CdS on faceted Si NWs were grown without removal of the Si NW native surface oxide prior to CdS deposition (FIG. 8A). In the upstream position, SEM images showed conformal CdS shells with rough surfaces that were consistent with deposition of a fully-polycrystalline shell. This contrasts with the well-developed {0001} facets observed when the native surface oxide was removed immediately prior to growth (FIG. 3A). In the downstream position, SEM images showed that no continuous CdS shell formed on any facets of the Si NWs with native oxide, in contrast to the facet-selective growth under the same conditions when the oxide was removed prior to growth (FIG. 11B).

Without wishing to be bound by any theory, it is noted that the facet-selective epitaxy on NW substrates appears to stem from (1) intrinsic “patterning” of the substrate with faceted NW structures, and/or (2) the natural formation of an oxide due to the difference in facet reactivity without the need for any lithographic patterning.

Therefore, the facet-selective epitaxy approach should be general for 1D Si structures and likely other NWs as well. To evaluate this, CdS was deposited on micrometer diameter Si wires (FIGS. 8B, 8C). SEM images of the resultant heterostructures revealed facet-selective growth of CdS on the Si{111} facets. Second, this was demonstrated with other shell materials by growing indium phosphide (InP) on faceted Si NWs. SEM imaging of InP growth carried out in a manner similar to the deposition of CdS (see below) on Si NWs (FIG. 8D) confirmed that InP islands grew selectively on the Si{111} facets and that the Si{113} facets remained free of InP.

FIGS. 8B (top), 8C show facet-selective CdS growth on Si wires of various sizes. SEM image of Si/CdS heterostructure wires with diameters of ca. (FIG. 8B, top) 3 micrometers and (FIG. 8C) 10 micrometers. Scale bars, 2 micrometers. FIG. 8C, left, SEM image of a Si/InP heterostructure NW. Scale bar, 400 nm. Right, schematic depicting the crystallography of the facet-selective Si/InP structure.

### Example 9

This example characterized the optical properties of the facet-selective Si/CdS heterostructure NWs. A scanning confocal photoluminescence image of facet-selective Si/CdS heterostructure NWs randomly dispersed on a quartz substrate (FIG. 9B) revealed strong green emission. Comparison of NW positions determined by bright-field and photoluminescence images demonstrated that every NW in this field of view exhibited strong luminescence. Moreover, a representative room temperature photoluminescence spectrum from a single Si/CdS NW (FIG. 9B) showed a symmetric emission profile, featuring strong band-edge emission at ˜514 nm (2.4 eV), which is consistent with high quality crystalline bulk CdS. No strong emissions were observed except for a band-edge peak, which may indicate that the CdS on the faceted Si NWs had a relatively low concentration of S-vacancy defects and was of high optical quality. Therefore, facet-selective Si/CdS NWs showed potential for integration of compound semiconductors with Si for (opto)electronics.

In summary, this examples demonstrate facet-selective growth of CdS on Si NWs. Aberration-corrected transmission electron microscopy analyses have shown that the crystalline CdS was grown epitaxially on the {111} and {110} surface facets of the Si NWs and that the Si{113} facets remained bare. Further analysis of conformal CdS shells on Si NWs grown at higher deposition rates revealed a thin oxide layer on the Si{113} facet, suggesting that the facet-selective growth is allowed by the formation of an oxide which prevented subsequent shell growth on the Si{113} NW facets. Further studies of the generality of facet-selective epitaxial growth demonstrated the potential of the technique on micro-to-mesoscale wires, which allows tuning of the lateral width of the compound semiconductor layer without lithographic patterning, and InP shell growth on Si NWs. In addition, photoluminescence imaging and spectroscopy showed that the epitaxial shells display strong and clean band edge emission, thus confirming their high photonic quality, suggesting that facet selective epitaxy on 1D Si structures could serve as a unique platform for integrating compound semiconductors with group-IV materials in (opto)electronics.

FIG. 9B shows optical characterization of the facet-selective Si/CdS heterostructure NWs. Top, scanning confocal photoluminescence image of facet-selective Si/CdS heterostructure NWs randomly dispersed on a quartz substrate. Bottom, room temperature photoluminescence spectrum from a single Si/CdS NW.

### Example 10

This example illustrates various materials and methods used in some of the above examples.

Faceted Si nanowires (NWs) with diameters from 200 to 400 nm were grown by depositing different thickness Si shells on ca. 100 nm diameter Si NW cores at 775-860° C. The growth substrate with the faceted Si NWs was dipped in buffered hydrofluoric acid (BHF; 5173-03; J. T. Baker) for 20 s to remove surface oxide, rinsed for 5 s in deionized water, and then submerged in liquid nitrogen to freeze remaining water on the NW/substrate chip; this process prevented collapse of the low-density NWs via capillary forces during liquid water evaporation. The frozen growth substrate was quickly transferred to the second zone of a 3-zone furnace and the furnace was evacuated to a base pressure of 50 mTorr. Once at base pressure, the furnace was purged three times each with Ar (semiconductor grade; Matheson Tri-Gas; 99.999%) and H₂ (ultrahigh purity; Airgas; 99.999%) and the pressure was set at ˜2.8 Torr with a flow rate of 20 sccm H₂. The 3-zone furnace is equipped with a quartz boat with adjustable position using a quartz transfer rod. Prior to the above evacuation and purge, the quartz transfer boat was loaded with either CdS powder (−325 mesh; Alfa Aesar; 99.999%) or milled InP powder (Alfa Aesar; 99.9999%). Once the temperature of zone 1 stabilized at 670-710° C., the quartz rod was used to position the precursor in the center of zone 1. CdS or InP shells were grown on the Si NWs in zone 2 at 450-550° C. for 5-40 minutes.

NWs were imaged directly on the growth substrate using a Zeiss Ultra Plus field emission scanning electron microscope (SEM). For plan-view transmission electron microscope (TEM) or scanning TEM (STEM) imaging, NWs were mechanically transferred from the growth substrate to amorphous-carbon coated copper TEM grids (Ted Pella). Cross-sections were prepared by deposition of a protective carbon layer and subsequent lift-out using a Zeiss NVision 40 dual-beam SEM/focused ion beam (FIB) equipped with an Omniprobe micromanipulator. Both the plan-view and cross section NW samples were characterized using an aberration-corrected Zeiss Libra MC TEM operating at 200 keV. STEM-based energy dispersive x-ray spectroscopy (EDS) elemental mapping characterization was completed using an aberration-corrected Hitachi HD-2700 STEM operating at 200 keV.

Photoluminescence images were recorded at room temperature using a scanning confocal microscope (FluoView FV1000; Olympus America Inc.) with 473 nm excitation and a 490-540 nm band pass filter to pass photoluminescence and block excitation laser light. Optical spectroscopy at room temperature utilized a home-built epifluorescence microscope. A continuous-wave 405 nm diode laser (LaserGlow Technologies) was collimated and focused to a ˜1 micrometer diameter spot with incident power ˜900 microwatts using a 40× objective lens (NA=0.75; Olympus America Inc.). The laser and luminescence were passed through a 405 nm dichroic and subsequently through two 450 nm long pass filters to remove excitation light and finally to a 150 mm spectrometer (SP150; Princeton Instruments; 300 lines mm⁻¹ grating) equipped with a CCD detector (NTE 2; Roper Scientific).

FIG. 8A shows CdS growth on faceted Si NWs without removing the Si native oxide prior to growth. SEM images of (top) upstream and (bottom) downstream Si/CdS heterostructure NWs grown without a BHF etch prior to CdS deposition. Upstream, the CdS deposited conformally on the NWs but lacks the well-developed surface facet seen in the NWs grown with BHF etch prior to CdS deposition as in FIG. 3; downstream, no continuous CdS shells deposit on the Si NWs, in contrast to those shown in FIG. 11. Scale bars, 1 micrometer.

While several embodiments of the present invention have been described and illustrated herein, those of ordinary skill in the art will readily envision a variety of other means and/or structures for performing the functions and/or obtaining the results and/or one or more of the advantages described herein, and each of such variations and/or modifications is deemed to be within the scope of the present invention. More generally, those skilled in the art will readily appreciate that all parameters, dimensions, materials, methods, and configurations described herein are meant to be exemplary and that the actual parameters, dimensions, materials, methods, and/or configurations will depend upon the specific application or applications for which the teachings of the present invention is/are used. Those skilled in the art will recognize, or be able to ascertain using no more than routine experimentation, many equivalents to the specific embodiments of the invention described herein. It is, therefore, to be understood that the foregoing embodiments are presented by way of example only and that, within the scope of the appended claims and equivalents thereto, the invention may be practiced otherwise than as specifically described and claimed. The present invention is directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the scope of the present invention.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

When the word “about” is used herein in reference to a number, it should be understood that still another embodiment of the invention includes that number not modified by the presence of the word “about.”

It should also be understood that, unless clearly indicated to the contrary, in any methods claimed herein that include more than one step or act, the order of the steps or acts of the method is not necessarily limited to the order in which the steps or acts of the method are recited.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of and” consisting essentially of shall be closed or semi-closed transitional phrases, respectively, as set forth in the United States Patent Office Manual of Patent Examining Procedures, Section 2111.03.

What is claimed is:

1. A method, comprising:
removing silicon oxide from at least a portion of a nanoscale wire comprising a silicon surface;
oxidizing a first facet of the nanoscale wire relative to a second facet; and
preferentially depositing material on the second facet relative to the first facet.

2. The method of claim 1, wherein the nanoscale wire consists essentially of silicon.

3. The method of any one of claim 1 or 2, wherein the deposited material is semiconducting.

4. The method of any one of claims 1-3, wherein the deposited material comprises CdS.

5. The method of any one of claims 1-4, wherein the deposited material comprises InP.

6. The method of any one of claims 1-5, wherein the deposited material comprises Si.

7. The method of any one of claims 1-6, wherein the deposited material consists essentially of Si.

8. The method of any one of claims 1-7, wherein the deposited material comprises Ge.

9. The method of any one of claims 1-8, wherein the deposited material consists essentially of Ge.

10. The method of any one of claims 1-9, wherein the first facet is a {011} facet.

11. The method of any one of claims 1-10, wherein the first facet is a {111} facet.

12. The method of any one of claims 1-11, wherein the second facet is a {113} facet.

13. The method of any one of claims 1-12, wherein removing silicon oxide comprises exposing the nanowire to an etchant.

14. The method of claim 13, wherein the etchant comprises HF.

15. The method of any one of claim 13 or 14, wherein the etchant comprises buffered HF.

16. The method of any one of claims 1-15, wherein the nanoscale wire is substantially crystalline.

17. The method of any one of claims 1-16, wherein the deposited material is substantially crystalline.

18. The method of any one of claims 1-17, wherein the nanoscale wire is a nanowire.

19. The method of any one of claims 1-18, wherein the nanoscale wire has a diameter of less than about 1 micrometer.

20. The method of any one of claims 1-19, wherein the nanoscale wire has a variation in average diameter of less than about 20%.

21. The method of any one of claims 1-20, further comprising depositing a second material on the deposited material of the nanoscale wire.

22. A nanoscale wire made by the method of any one of claims 1-21.

23. A method, comprising:
applying an etchant to a nanoscale wire comprising a silicon surface;
oxidizing a first facet of the etched nanoscale wire relative to a second facet; and
preferentially depositing material on the second facet relative to the first facet.

24. The method of claim 23, wherein the deposited material is semiconductive.

25. The method of any one of claim 23 or 24, wherein the deposited material comprises CdS.

26. The method of any one of claims 23-25, wherein the deposited material comprises InP.

27. The method of any one of claims 23-26, wherein the deposited material comprises Si.

28. The method of any one of claims 23-27, wherein the deposited material comprises Ge.

29. The method of any one of claims 23-28, wherein the first facet is a {011} facet.

30. The method of any one of claims 23-28, wherein the first facet is a {111} facet.

31. The method of any one of claims 23-30, wherein the second facet is a {113} facet.

32. The method of any one of claims 23-31, wherein the etchant comprises HF.

33. The method of any one of claims 23-32, wherein the etchant comprises buffered HF.

34. A nanoscale wire made by the method of any one of claims 23-33.

35. A method, comprising:
removing silicon oxide from at least a portion of a faceted nanoscale wire;
freeze-drying the nanoscale wire; and
preferentially depositing material on a second facet relative to a first facet of the nanoscale wire.

36. The method of claim 35, comprising removing silicon oxide from at least one facet of the nanoscale wire.

37. The method of any one of claim 35 or 36, wherein freeze-drying the nanoscale wire comprises exposing the nanoscale wire to liquid nitrogen.

38. The method of any one of claims 35-37, wherein freeze-drying the nanoscale wire comprises exposing the nanoscale wire to a temperature below about −150° C.

39. The method of any one of claims 35-38, wherein freeze-drying the nanoscale wire comprises exposing the nanoscale wire to a pressure of less than 100 mTorr.

40. The method of any one of claims 35-39, wherein freeze-drying the nanoscale wire comprises exposing the nanoscale wire to a pressure of less than 50 mTorr.

41. The method of any one of claims 35-40, wherein the deposited material is semiconductive.

42. The method of any one of claims 35-41, wherein the deposited material comprises CdS.

43. The method of any one of claims 35-42, wherein the deposited material comprises InP.

44. The method of any one of claims 35-43, wherein the deposited material comprises Si.

45. The method of any one of claims 35-44, wherein the deposited material comprises Ge.

46. The method of any one of claims 35-45, wherein the first facet is a {011} facet.

47. The method of any one of claims 35-45, wherein the first facet is a {111} facet.

48. The method of any one of claims 35-47, wherein the second facet is a {113} facet.

49. The method of any one of claims 35-48, wherein the etchant comprises HF.

50. The method of any one of claims 35-49, wherein the etchant comprises buffered HF.

51. A nanoscale wire made by the method of any one of claims 35-50.

52. A method, comprising:
preferentially oxidizing a first facet of a faceted nanoscale wire relative to a second facet; and
preferentially depositing material on the second facet of the nanoscale wire relative to the first facet.

53. A nanoscale wire made by the method of claim 52.

54. A method, comprising:
removing an oxide from at least a portion of a surface of a crystalline semiconductor nanoscale wire;
oxidizing a first facet of the nanoscale wire relative to a second facet; and
preferentially depositing material on the second facet relative to the first facet.

55. A nanoscale wire made by the method of claim 54.

56. A method, comprising:
applying an etchant to a crystalline nanoscale wire;
oxidizing a first facet of the etched nanoscale wire relative to a second facet; and
preferentially depositing material on the second facet relative to the first facet.

57. The method of claim 56, wherein the nanoscale wire is a semiconductor nanoscale wire.

58. A nanoscale wire made by the method of any one of claim 56 or 57.

59. A method, comprising:
removing an oxide from at least a portion of a crystalline nanoscale wire;
freeze-drying the nanoscale wire; and
depositing material on a second facet relative to a first facet of the nanoscale wire.

60. The method of claim 59, wherein the nanoscale wire is a semiconductor nanoscale wire.

61. A nanoscale wire made by the method of any one of claim 60 or 61.

62. A method, comprising:
removing an oxide from at least a portion of a surface of a semiconductor;
oxidizing a first facet of the surface relative to a second facet; and
preferentially depositing material on the second facet relative to the first facet.

63. The method of claim 62, wherein the surface is the surface of a semiconductor.

64. A nanoscale wire made by the method of any one of claim 62 or 63.

65. A method, comprising:
applying an etchant to a crystalline surface;
oxidizing a first facet of the etched surface relative to a second facet; and
preferentially depositing material on the second facet relative to the first facet.

66. The method of claim 65, wherein the surface is the surface of a semiconductor.

67. The method of any one of claim 65 or 66, comprising oxidizing the first facet to form an oxide of the semiconductor forming the surface.

68. A nanoscale wire made by the method of any one of claims 65-67.

69. A method, comprising:
removing an oxide from at least a portion of a crystalline surface;
freeze-drying the surface; and
depositing material on a second facet relative to a first facet of the surface.

70. The method of claim 69, wherein the surface is the surface of a semiconductor.

71. A nanoscale wire made by the method of any one of claims 69-70.

72. A method, comprising:
preferentially oxidizing a first facet of a crystalline surface relative to a second facet; and
preferentially depositing material on the second facet relative to the first facet.

73. The method of claim 72, wherein the surface is the surface of a semiconductor.

74. A nanoscale wire made by the method of any one of claim 72 or 73.

75. A method, comprising:
removing silicon oxide from at least a portion of a faceted nanoscale wire;
critical point drying the nanoscale wire; and
preferentially depositing material on a second facet relative to a first facet of the nanoscale wire.

76. The method of claim 75, comprising removing silicon oxide from at least one facet of the nanoscale wire.

77. A nanoscale wire made by the method of any one of claim 75 or 76.

78. A method, comprising:
removing an oxide from at least a portion of a crystalline nanoscale wire;
critical point drying the nanoscale wire; and
depositing material on a second facet relative to a first facet of the nanoscale wire.

79. The method of claim 78, wherein the nanoscale wire is a semiconductor nanoscale wire.

80. A nanoscale wire made by the method of any one of claim 78 or 79.

81. A method, comprising:
removing an oxide from at least a portion of a crystalline surface;
critical point drying the surface; and
depositing material on a second facet relative to a first facet of the surface.

82. The method of claim 81, wherein the nanoscale wire is a semiconductor nanoscale wire.

83. A nanoscale wire made by the method of any one of claim 81 or 82.

84. A method, comprising:
removing silicon oxide from at least a portion of a nanoscale wire comprising a silicon surface;
oxidizing a first facet of the nanoscale wire relative to a second facet; and
preferentially depositing material on the first facet relative to the second facet.

85. The method of claim 84, wherein the material is As, Ti, Cr, Zr, Fe, Co, V, Al, Li, Na, K, Rb, Cs, Mg, Ca, Sc, Nb, Mn, Ni, Zn, or Ce.

86. The method of any one of claim 84 or 85, wherein the material is aluminum oxide.

87. The method of any one of claims 84-86, wherein the material is silicon oxide.

88. The method of any one of claims 84-87, wherein the material is silicon nitride.

89. A nanoscale wire made by the method of any one of claims 84-88.

90. A method, comprising:
applying an etchant to a nanoscale wire comprising a silicon surface;
oxidizing a first facet of the etched nanoscale wire relative to a second facet; and
preferentially depositing material on the first facet relative to the second facet.

91. A nanoscale wire made by the method of claim 90.

92. A method, comprising:
removing silicon oxide from at least a portion of a faceted nanoscale wire;
freeze-drying the nanoscale wire; and
preferentially depositing material on a first facet relative to a second facet of the nanoscale wire.

93. The method of claim 92, comprising removing silicon oxide from at least one facet of the nanoscale wire.

94. A nanoscale wire made by the method of any one of claim 92 or 93.

95. A method, comprising:
preferentially oxidizing a first facet of a faceted nanoscale wire relative to a second facet; and
preferentially depositing material on the first facet of the nanoscale wire relative to the second facet.

96. A nanoscale wire made by the method of claim 95.

97. A method, comprising:
removing an oxide from at least a portion of a surface of a crystalline semiconductor nanoscale wire;
oxidizing a first facet of the nanoscale wire relative to a second facet; and
preferentially depositing material on the first facet relative to the second facet.

98. A nanoscale wire made by the method of claim 97.

99. A method, comprising:
applying an etchant to a crystalline nanoscale wire;
oxidizing a first facet of the etched nanoscale wire relative to a second facet; and
preferentially depositing material on the first facet relative to the second facet.

100. The method of claim 99, wherein the nanoscale wire is a semiconductor nanoscale wire.

101. A nanoscale wire made by the method of any one of claim 99 or 100.

102. A method, comprising:
removing an oxide from at least a portion of a crystalline nanoscale wire;
freeze-drying the nanoscale wire; and
depositing material on a first facet relative to a second facet of the nanoscale wire.

103. The method of claim 102, wherein the nanoscale wire is a semiconductor nanoscale wire.

104. A nanoscale wire made by the method of any one of claim 102 or 103.

105. A method, comprising:
removing an oxide from at least a portion of a surface of a semiconductor;
oxidizing a first facet of the surface relative to a second facet; and
preferentially depositing material on the first facet relative to the second facet.

106. The method of claim 105, wherein the surface is the surface of a semiconductor.

107. A nanoscale wire made by the method of any one of claim 105 or 106.

108. A method, comprising:
applying an etchant to a crystalline surface;
oxidizing a first facet of the etched surface relative to a second facet; and
preferentially depositing material on the first facet relative to the second facet.

109. The method of claim 108, wherein the surface is the surface of a semiconductor.

110. The method of any one of claim 108 or 109, comprising oxidizing the first facet to form an oxide of the semiconductor forming the surface.

111. A nanoscale wire made by the method of any one of claims 108-110.

112. A method, comprising:
removing an oxide from at least a portion of a crystalline surface;
freeze-drying the surface; and
depositing material on a first facet relative to a second facet of the surface.

113. The method of claim 112, wherein the surface is the surface of a semiconductor.

114. A nanoscale wire made by the method of any one of claim 112 or 113.

115. A method, comprising:
preferentially oxidizing a first facet of a crystalline surface relative to a second facet; and
preferentially depositing material on the first facet relative to the second facet.

116. The method of claim 115, wherein the surface is the surface of a semiconductor.

117. A nanoscale wire made by the method of any one of claim 115 or 116.

118. A method, comprising:
removing silicon oxide from at least a portion of a faceted nanoscale wire;
critical point drying the nanoscale wire; and
preferentially depositing material on a second facet relative to a first facet of the nanoscale wire.

119. The method of claim 118, comprising removing silicon oxide from at least one facet of the nanoscale wire.

120. A nanoscale wire made by the method of any one of claim 119 or 120.

121. A method, comprising:
removing an oxide from at least a portion of a crystalline nanoscale wire;
critical point drying the nanoscale wire; and
depositing material on a second facet relative to a first facet of the nanoscale wire.

122. The method of claim 121, wherein the nanoscale wire is a semiconductor nanoscale wire.

123. A nanoscale wire made by the method of any one of claim 121 or 122.

124. A method, comprising:
removing an oxide from at least a portion of a crystalline surface;
critical point drying the surface; and
depositing material on a second facet relative to a first facet of the surface.

125. The method of claim 124, wherein the nanoscale wire is a semiconductor nanoscale wire.

126. A nanoscale wire made by the method of any one of claim 124 or 125.

127. A method, comprising:
removing an oxide from at least a portion of a crystalline semiconductor surface using an etchant;
freeze-drying the surface;
preferentially oxidizing a first facet of the crystalline semiconductor surface relative to a second facet; and
preferentially depositing material on the second facet relative to the first facet.

128. A nanoscale wire made by the method of claim 127.

129. A composition, comprising:
a silicon nanoscale wire comprising a first facet and a second facet, and a material positioned on the first facet but not the second facet, wherein the interface between the first facet and the silicon nanoscale wire is substantially free of oxygen.
